(19) United States
(12) Patent Application Publication
(10) Pub. No.: US 2025/0085400 A1
(43) Pub. Date: Mar. 13, 2025

(54) Optical Module

(71) Applicant: Apple Inc., Cupertino, CA (US)

(72) Inventors: Xiaoyin Zhu, San Jose, CA (US); Ali M. Khan, San Francisco, CA (US); Andrea Manavella, San Francisco, CA (US); Andrej Halabica, San Jose, CA (US); April D. Schriker, Mountain View, CA (US); Austin Y. Seol, Cupertino, CA (US); Bhavin J. Bijlani, San Diego, CA (US); Caihua Chen, Albany, NY (US); Chin Han Lin, Santa Clara, CA (US); Cristiano L. Niclass, San Jose, CA (US); David Sicard, Singapore (SG); Eric D. Aspnes, San Diego, CA (US); Hazel A. McInnes, Santa Clara, CA (US); Henry M. Daghighian, Cupertino, CA (US); Igor Raginski, San Diego, CA (US); Jiayang Cao, Cupertino, CA (US); Jibum Cha, Yongin (KR); Jili Liu, Cupertino, CA (US); Jose M. Infante Herrero, Los Gatos, CA (US); Julien Sarry, San Francisco, CA (US); Karen A. Cabrera, San Mateo, CA (US); Lorenzo Ferrari, San Diego, CA (US); Niv Gilboa, Tel Aviv (IL); Noriaki Saika, Foster City, CA (US); Pietro R. Binetti, San Jose, CA (US); Pushkar Pandit, San Jose, CA (US); Reema Shalan, Cupertino, CA (US); Scott T. Smith, San Jose, CA (US); Shifa Xu, Palo Alto, CA (US); Shingo Mandai, Palo Alto, CA (US); Shujun Tang, Santa Cruz, CA (US); Sibi Sutty, Imperial Beach, CA (US); Susan A. Thompson, Buckley, WA (US); Teimour T. Maleki, Thousand Oaks, CA (US); Thierry Oggier, Langlau am Albis (CH); Vikrant Dhamdhere, Cupertino, CA (US); Yohai Zmora, San Francisco, CA (US); Yuanlin Xie, Fremont, CA (US); Wee Keat Chong, Singapore (SG)

(21) Appl. No.: 18/830,624

(22) Filed: Sep. 11, 2024

Related U.S. Application Data
(60) Provisional application No. 63/581,684, filed on Sep. 11, 2023.
(60) Provisional application No. 63/581,687, filed on Sep. 11, 2023.
(60) Provisional application No. 63/581,686, filed on Sep. 11, 2023.

(51) Int. Cl. G01S 7/481; G01S 17/894; G03B 30/00; H04N 13/239; H04N 23/51; H04N 23/56; H04N 23/74

(52) U.S. Cl. CPC G01S 7/4815; G01S 17/894; G03B 30/00; H04N 13/239; H04N 23/51; H04N 23/56; H04N 23/74; G01S 7/4813

(57) ABSTRACT

An optoelectronic assembly includes: (i) a substrate having a cavity, (ii) an optoelectronic device, which is disposed over the cavity and includes an array of multiple emitters configured to emit a predefined number of light beams in response to receiving one or more electrical signals, and (iii) an integrated circuit (IC), which is mounted within the cavity, between the substrate and the optoelectronic device, and is configured to drive the one or more electrical signals to the optoelectronic device.

### CROSS-REFERENCE TO RELATED APPLICATIONS

This application claims the benefit of U.S. Provisional Patent Applications 63/581,684, 63/581,686, and 63/581,687, all filed Sep. 11, 2023. The disclosures of these related applications are incorporated herein by reference.

### FIELD OF THE INVENTION

The present invention relates generally to devices and methods for optical sensing, and particularly to optical transmitter/receiver modules.

### BACKGROUND

Some types of optical sensing systems comprise an optical transmitter, which transmits a beam of optical radiation toward a target, and an optical receiver, which collects and senses the optical radiation that is reflected from the target. In the context of the present description and in the claims, the term “optical radiation,” refers to electromagnetic radiation in any of the visible, infrared, and ultraviolet spectral ranges, and may be used interchangeably with the term “light.”

For example, in some depth sensing systems, the transmitter emits pulses of radiation toward a target, and the optical receiver senses the times of flight (ToF) of the pulses, and thereby measures the distance to the target.

For many sensing applications, comprising ToF-based depth sensing, it can be advantageous to package the transmitter and receiver together on the same substrate in a compact package. Integrated optoelectronic modules of this sort are described, for example, in U.S. Pat. Nos. 11,681,019, and 9,157,790, whose disclosures are incorporated herein by reference.

ToF-based depth sensing devices are almost inevitably subject to stray reflections, which reflect or otherwise scatter from optical surfaces within the device back toward the receiver. In general, such stray reflections are regarded as noise, and designers of the devices do their best to eliminate them. On the other hand, U.S. Pat. No. 9,335,220, whose disclosure is incorporated herein by reference, describes a ToF-based scanner in which the stray reflections are used intentionally in calibrating the ToF measurements.

In the disclosed scanner, a transmitter emits a beam comprising optical pulses toward a scene, and a receiver receives reflections of the optical pulses and outputs electrical signals in response thereto. Processing circuitry is coupled to the receiver so as to receive, in response to each of at least some of the optical pulses emitted by the transmitter, a first electrical signal output by the receiver at a first time due to stray reflection within the apparatus, and a second electrical signal output by the receiver at a second time due to the beam reflected from the scene. The processing circuitry generates a measure of the time of flight of the optical pulses to and from points in the scene by taking a difference between the respective first and second times of output of the first and second electrical signals.

### SUMMARY OF THE INVENTION

An embodiment of the present invention that is described herein provides an optoelectronic assembly, including (i) a substrate having a cavity, (ii) an optoelectronic device, which is disposed over the cavity and includes an array of multiple emitters configured to emit a predefined number of light beams in response to receiving one or more electrical signals, and (iii) an integrated circuit (IC), which is mounted within the cavity, between the substrate and the optoelectronic device, and is configured to drive the one or more electrical signals to the optoelectronic device.

In some embodiments, the optoelectronic assembly includes electrically conductive bumps, which are disposed between the IC and the optoelectronic device and are configured to conduct the one or more electrical signals.

In other embodiments, the optoelectronic assembly includes a lens assembly mounted over the optoelectronic device and configured to direct a given number of light beams to a scene opposite the lens assembly, and the given number equals the predefined number of the light beams emitted from the optoelectronic device.

In yet other embodiments, the optoelectronic assembly includes a housing, which is mounted over the substrate and is configured to shield at least the optoelectronic device and the IC from electromagnetic interference (EMI), and at least a portion of the lens assembly extends out of the housing.

In some embodiments, the optoelectronic assembly is mounted on a handheld device and is configured to direct the given number of light beams to the scene for producing a three-dimensional (3D) image of the scene, and the 3D image has a field-of-view (FOV) orthogonal to an axis, which is directed at an acute angle relative to a plain of a chassis of the handheld device.

In other embodiments, the optoelectronic assembly includes a filler, which is disposed between an edge of the IC and the cavity, and surrounds the edge of the IC, the filler is configured to protect the IC from light radiation impinging on at least the edge of the IC.

In yet other embodiments, the light radiation includes a portion of the light beams reflected from one or both of the lens assembly and/or the housing, and the filler includes resin configured to attenuate at least a predefined wavelength of the reflected light beams.

There is additionally provided, in accordance with an embodiment of the present invention a handheld device, including (a) a camera, which is configured to acquire at least an image of a scene, the image of the camera has a first field-of-view (FOV) orthogonal to a first axis directed at a first angle relative to a plain of a chassis of the handheld device, and (b) an optoelectronic device, disposed at a predefined distance from the camera, the optoelectronic device including: (i) an optical transmitter configured to direct multiple light beams toward the scene, and (ii) an optical receiver positioned alongside the optical transmitter, the optical receiver including a time-of-flight (TOF) imaging sensor, which configured to generate, based on a reflection of the multiple light beams directed toward the scene, a signal indicative of a three-dimensional (3D) image of the scene, and the 3D image has a second FOV orthogonal to a second axis directed at a second angle relative to the plain of the chassis, the second angle is different from the first angle, and the first and second angles are tilted toward one another to increase an overlap between the first and second FOVs.

In some embodiments, the handheld device includes a base plate, which is slanted relative to the plain of the chassis, and the camera or the optoelectronic device is mounted on the base plate. In other embodiments, the base plate has a third axis, which is slanted at a third angle relative to the plain of the chassis, a sum of the second angle and the third angle equals a right angle, and the optoelectronic device is mounted on the base plate.

In yet other embodiments, the optoelectronic device includes a substrate, which is (i) disposed on the base plate, and (ii) slanted relative to the plain of the chassis, and the optical transmitter and the optical receiver are mounted on the substrate.

In some embodiments, the handheld device includes a first housing disposed on the substrate, the first housing is configured to contain the optical transmitter and the optical receiver, the optical transmitter has a transmit axis, and the optical receiver has a receive axis, and at least one of the transmit axis and the receive axis is parallel to the second axis.

In other embodiments, the first housing is slanted, and the handheld device includes a second housing of the electronic device, the second housing is disposed on the first housing and has an asymmetric shape.

In yet other embodiments, the second housing has (i) a first section disposed on a first side of the first housing at a first distance from the plain of the chassis, and (ii) a second section disposed on a second side of the first housing at a second distance from the plain of the chassis, different from the first distance.

In some embodiments, the second housing is configured to hold a plate configured to seal at least one of the optical transmitter and the optical receiver of the optoelectronic device. In other embodiments, the plate has an inner surface facing the optoelectronic device and an outer surface opposite the inner surface, and at least one of the inner surface and the outer surface is parallel with the plain of the chassis.

There is further provided, in accordance with an embodiment of the present invention, an optoelectronic device, including (i) a substrate, (ii) an optical transmitter having a first integrated circuit (IC), and an optical receiver having a second IC, the optical transmitter and the optical receiver are mounted on the substrate, and the first and second ICs generate electromagnetic interference (EMI) while being operated, (iii) a shield assembly, which is mounted over the substrate and is configured to encapsulate at least the first and second ICs, and to protect components positioned externally to the optoelectronic device from the EMI generated by the first and second ICs, and (iv) two or more grounding elements connecting between respective two or more dedicated locations of the shield and a common electrical ground point.

In some embodiments, the shield assembly has a polygonal shape, and the two or more dedicated locations include two or more apexes of the polygonal shape, respectively. In other embodiments, the shield assembly is configured to protect at least one of the first and second ICs from an external EMI generated by an electromagnetic source positioned externally to the optoelectronic device.

There is additionally provided, in accordance with an embodiment of the present invention, an optoelectronic device, including: (i) an optical transmitter positioned at a first side of a wall, the optical transmitter including: (a) an optoelectronic device configured to emit multiple light beams, a first portion of the light beams is directed toward a scene, and a second portion of the light beams include internal stray light beams (SLBs) that are not directed toward the scene, and (b) a retainer ring, which is at least partially surrounding the optoelectronic device, and is configured to direct the internal SLBs through an opening in the wall, and (ii) an optical receiver positioned alongside the optical transmitter at a second side of the wall, the optical receiver including: (a) a first array of imaging pixels, which is configured to generate a first signal based on the emitted light beams reflected from the scene, and a second signal responsively to receiving first internal SLBs among the SLBs that pass through the opening, and (b) a second array of imaging pixels, which is separated from the first array, and is configured to generate a third signal responsively to receiving second internal SLBs among the SLBs that pass through the opening.

In some embodiments, the first array of imaging pixels includes a time-of-flight (TOF) imaging sensor, and the optoelectronic assembly further includes a processor, which is configured to produce a three-dimensional (3D) image of the scene based on the first signal and at least one of the second and third signals, and the second and third signals serve as TOF reference for producing the 3D image.

In other embodiments, the optoelectronic assembly includes: (i) a lens assembly mounted over the optoelectronic device, the lens assembly including at least first and second lens, and is configured to direct at least a portion of the light beams toward the scene, and (ii) a lens aperture, mounted between the first lens and the second lens, and configured to block at least a portion of external SLBs being reflected from a glass covering the optoelectronic assembly into the lens assembly. In yet other embodiments, the lens aperture has a horus shape having an outer diameter and an inner diameter, and the size of at least one of the outer and inner diameters determines the portion of the external SLBs blocked by the lens aperture.

In some embodiments, the optoelectronic assembly includes a stack of multiple layers, which are formed on an outer surface of at least one of the first lens and the second lens, the stack of multiple layers is configured to selectively reflect at least a portion of the internal SLBs at predefined angles through the opening in the wall toward at least one of the first and second arrays of imaging pixels.

In other embodiments, the stack of multiple layers includes alternating layers of (i) titanium oxide and (ii) silicon oxide which are configured to control an intensity of at least one of the first and second internal SLBs impinging on a surface of at least one of the first and second arrays of imaging pixels, respectively.

The present invention will be more fully understood from the following detailed description of the embodiments thereof, taken together with the drawings in which:

### BRIEF DESCRIPTION OF THE DRAWINGS

FIG. 1 is a schematic pictorial illustration of an optical module, in accordance with an embodiment of the invention;

FIG. 2 is a schematic sectional view of the optical module of FIG. 1, in accordance with an embodiment of the invention;

FIG. 3A is a schematic, top view of stray light beams directed between an optical transmitter and an optical receiver of the optical module of FIG. 1, in accordance with an embodiment of the invention;

FIG. 3B is a schematic pictorial illustration of a case of the optical module of FIG. 1, in accordance with an embodiment of the invention;

FIG. 4 is a schematic sectional view of an optical transmitter of the optical module of FIG. 1, in accordance with an embodiment of the invention;

FIG. 5 is a schematic sectional view of multiple optical modules, in accordance with an embodiment of the invention;

FIG. 6 is a schematic sectional view of optical transmitter of the optical module of FIG. 1, in accordance with another embodiment of the invention;

FIG. 7 is a schematic top view of optical transmitter of the optical module of FIG. 1, in accordance with another embodiment of the invention;

FIG. 8 is a schematic illustration of a driver circuitry of the optical transmitter of FIG. 4, in accordance with an embodiment of the invention;

FIG. 9 is a sectional view of the optical module of FIG. 1 integrated in a handheld electronic device, in accordance with an embodiment of the invention;

FIG. 10 is a side view of the optical module of FIG. 1 integrated in another handheld electronic device, in accordance with another embodiment of the invention;

FIG. 11 is a flow chart that schematically illustrates a method for producing the optical module of FIG. 2, in accordance with an embodiment of the invention;

FIG. 12 is a flow chart that schematically illustrates a method for producing the handheld device of FIG. 10, in accordance with an embodiment of the invention;

FIG. 13 is a flow chart that schematically illustrates a method for producing the optical modules of FIGS. 1 and 2 and shielding components in proximity with the optical modules of FIGS. 1 and 2, in accordance with an embodiment of the invention; and

FIG. 14 is a flow chart that schematically illustrates a method for producing the optoelectronic assembly of FIGS. 3A and 3B, in accordance with another embodiment of the invention.

### DETAILED DESCRIPTION OF EMBODIMENTS

In designing an optical module, which is packaged in an electronic device, and includes a transmitter and a receiver, it is important to eliminate or at least mitigate several problems associated with the structure and the operation of the optical module and the electronic device. More specifically, as described in more detail below, it is important to: (i) reduce the height of the optical module in order to reduce the size of the electronic device (e.g., a handheld device), (ii) manage the electric charge distribution to reduce electromagnetic interference (EMI) generated during the operation of the optical module in conjunction with the operation of the electronic device, and (iii) minimize the amount of and the impact of stray light radiation that reaches at least one of the receiver and integrated circuits (ICs) of the optical module.

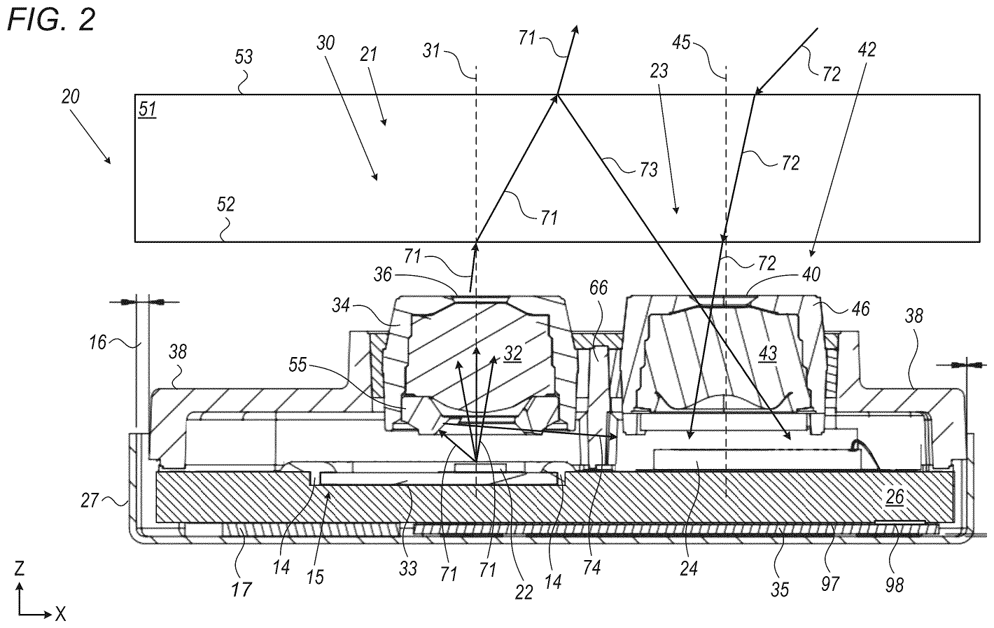

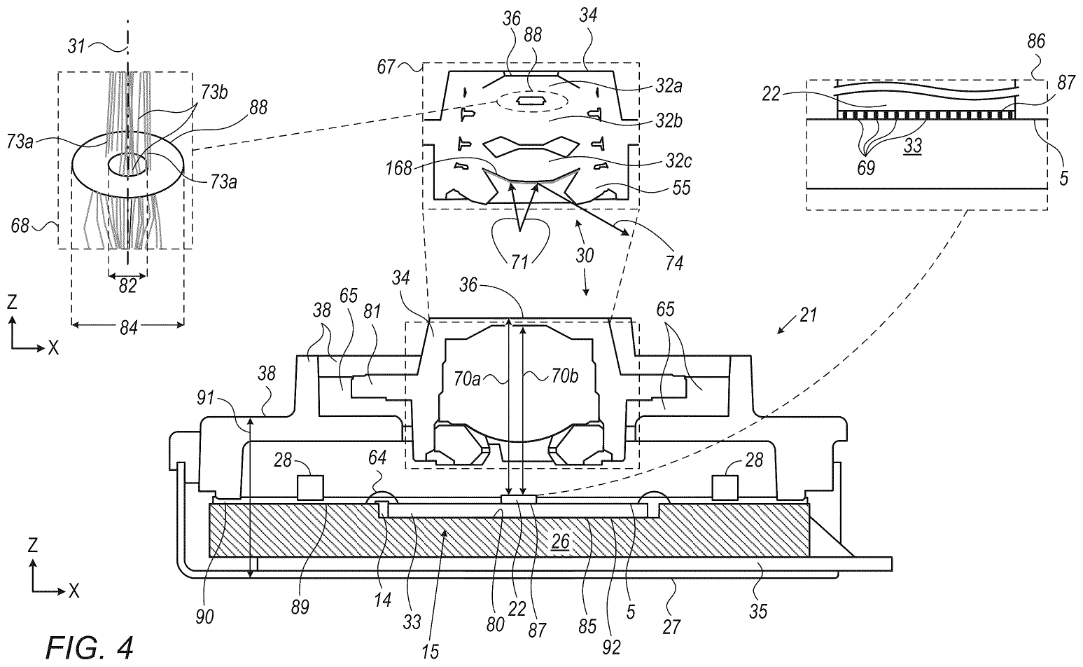

Typically, an axis that determines the thickness of the electronic device that comprises the optical module, is approximately orthogonal to the axes of light emitted from and detected by the optical module. As such, in some cases, the height of the optical module may determine the thickness of the electronic device. Therefore, it is important to reduce the height of the optical module, e.g., for reducing the size and the power consumption of the electronic device. Embodiments of the invention that are described in FIGS. 2 and 4 below address techniques for reducing the height of the optical module.

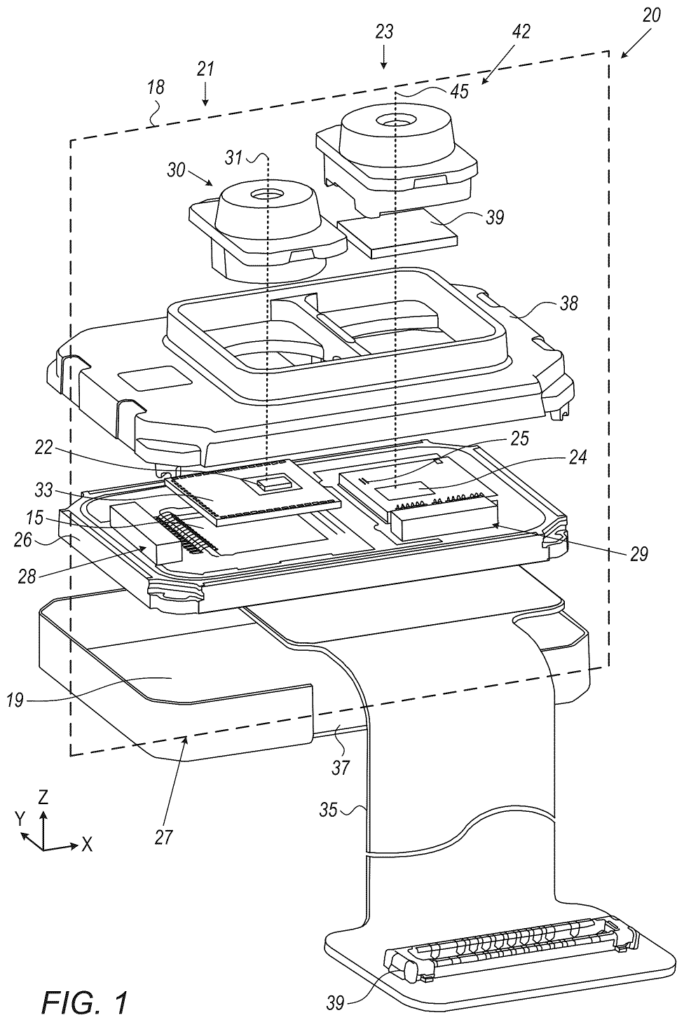

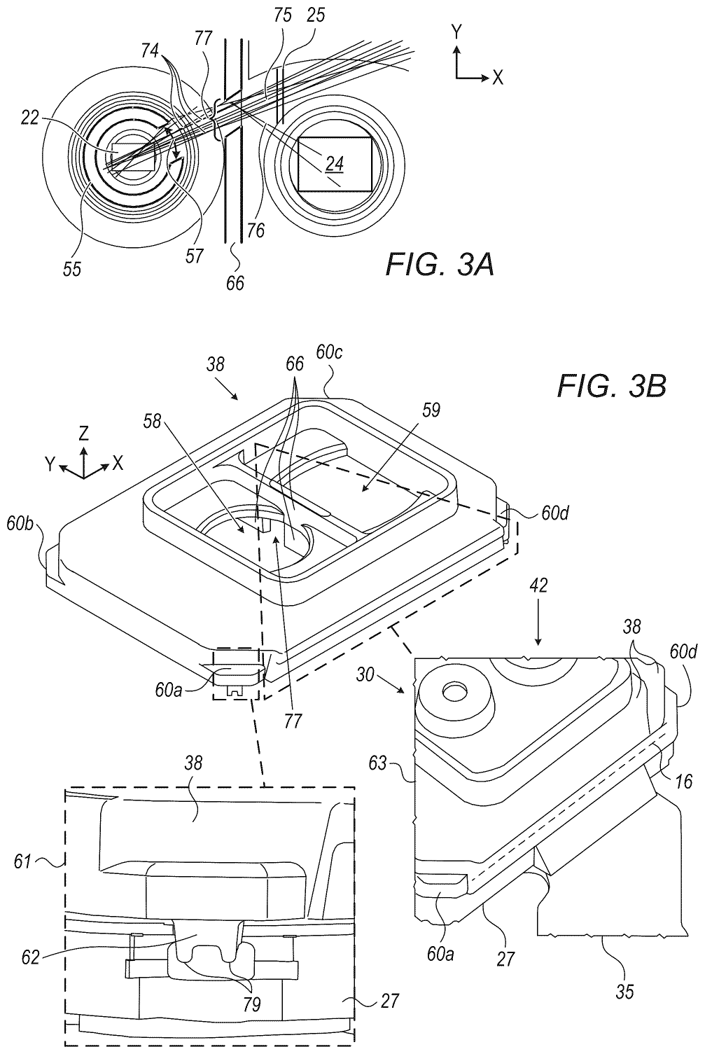

As described, for example, in FIGS. 1 and 2 below, the optical module and the electronic comprise components that may generate electromagnetic interference (EMI) and/or receive EMI from an external source. In accordance with embodiments of the invention, techniques for mitigating the EMI generated within the optical module and exchanged between the optical module and external sources of EMI, are described in detail in FIGS. 2 and 3B below.

In the context of the present disclosure and in the claims, the terms “stray light,” “stray beam” and “stray radiation” refer to optical radiation that does not (i) exit the optical module along the intended transmit path toward the target, and then (ii) return from the target to the receiver through an objective lens assembly of the optical module. As such, stray light is reflected internally within the optical module, typically from one or more of the optical and/or mechanical surfaces in the optical module. It is noted that even a small amount of this sort of stray radiation can severely degrade the performance of the optical module, e.g., by adding substantial noise to the signals output by the receiver of the optical module. In accordance with embodiments of the invention, techniques for mitigating the level of stray light, and the impact of stray light on the performance of the optical module, are described in detail in FIGS. 2, 3A, 3B, 4, 5, 6, and 7 below.

FIG. 1 is a schematic pictorial illustration of an optical device referred to herein as an optical module 20, in accordance with an embodiment of the invention. In the context of the present disclosure and in the claims, the terms optical module 20, module 20, optical device, and opto-electronic assembly, are used interchangeably. In the present example, FIG. 1 shows an exploded view of optical module 20 along a Z-axis of an XYZ coordinate system of optical module 20, in order to show the main components thereof.

FIG. 2 is a schematic sectional view of optical module 20, in accordance with an embodiment of the invention. In the present example, the sectional view is presented over a plain 18 (which is coplanar with an XZ plane of the XYZ coordinate system) shown in FIG. 1.

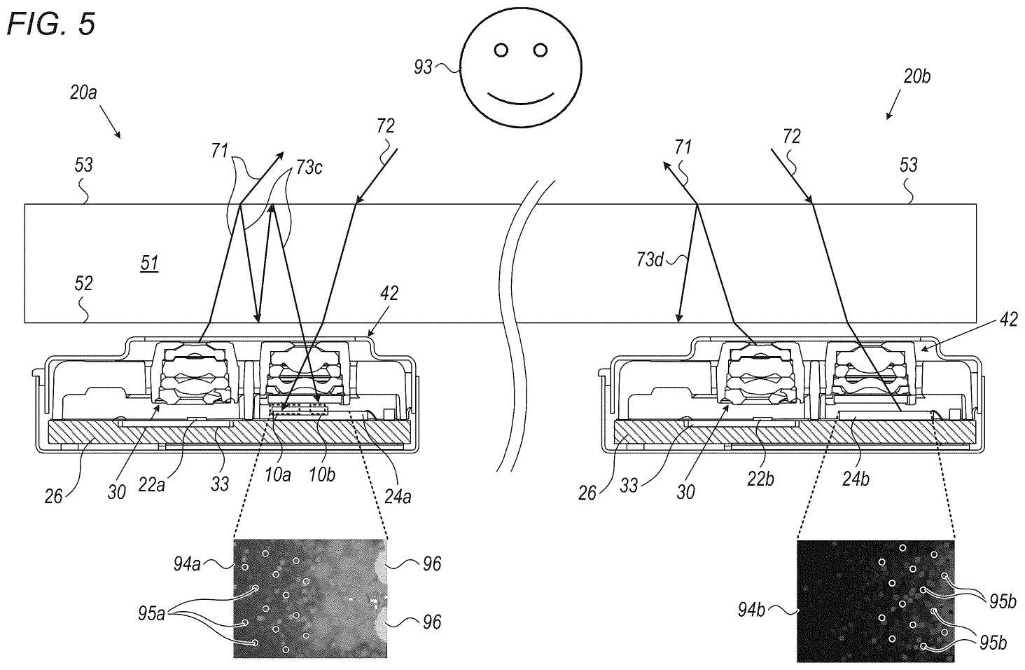

Reference is now made to FIG. 1. In some embodiments, module 20 comprises an optical transmitter 21 and an optical receiver 23, which are mounted one alongside the other on a substrate 26. In the present example, module 20 is configured to sense depth of a target (e.g., shown in FIG. 5 below), which is external to module 20. As such, optical transmitter 21 is configured to emit pulses of optical radiation toward the target, and optical receiver 23 is configured to sense the optical radiation reflected from the target, and the times of flight (ToF) of the pulses. Based on the sensed optical radiation and the ToF, a processing unit (not shown) of optical module 20 and/or the electronic device (comprising module 20), is configured to measure the distance between the target and module 20.

In some embodiments, module 20 comprises a stiffener 27 made from a suitable metal or metallic alloy, such as phosphor bronze. For example, the phosphor bronze may comprise an alloy of (i) between about 0.03% and 0.35% of phosphorus, (ii) between about 3% and 9% of tin, and between 91% and 97% of copper. Moreover, stiffener 27 is coated (using any suitable plating technique) with a layer of nickel having a thickness between about 2 μm and 5 μm, and a phosphor content between about 7% and 13% in the plated nickel layer. Stiffener 27 is configured to enclose the lower surface (along the Z-axis) of substrate 26, and to stiffen the lower part of module 20. Moreover, stiffener 27 has an opening 37 whose functionality is described below.

In some embodiments, module 20 comprises an electrical circuit substrate, such as a flexible printed circuit board (CB), referred to herein as a CB 35, which is disposed between a surface 19 of stiffener 27, and the lower surface (not shown) of substrate 26. The arrangement of substrate 26, CB 35, and stiffener 27 are shown in the sectional view of FIG. 2 below.

In other embodiments, stiffener 27 (or at least a portion thereof) may be omitted from the configuration of module 20. It is noted that excluding stiffener 27 from the configuration of module 20 is applicable in case module 20 has sufficient inherent stiffness and/or sufficient mechanical support from the components surrounding module 20. The elimination of stiffener 27 may simplify the fabrication and reduce the costs of module 20.

In some embodiments, CB 35 extends out of opening 37, and is connected to a connector 39. As such, CB 35 and connector 39 are configured to exchange electrical signals between module 20 and devices external to module 20, such as a power supply unit (not shown), and integrated circuits (ICs) of the electronic device.

In some embodiments, transmitter 21 comprises an optical emitter 22, for example a suitable light-emitting diode (LED) or laser, such as a vertical-cavity surface-emitting laser (VCSEL), or an array of such LEDs or lasers, which may emit pulsed, continuous, or modulated radiation.

In the example of FIG. 1, CB 35 has a flat shape (i.e., without bents and/or folds in the CB) between substrate 26 and connector 39. In other embodiments, in addition to or instead of CB 35, module 20 may comprise a flexible circuit board configured to endure severe radial bending (e.g., bending at an acute angle). In such embodiments, the flexible circuit board with severe radial bending can be implemented to reduce the footprint of module 20 in the electronic device.

Reference is now made to FIG. 2. In some embodiments, transmitter 21 further comprises an integrated circuit (IC), in the present example, a driver 33, which is disposed within a cavity 15 in substrate 26. Driver 33 is configured to receive signals from CB 35 through substrate 26, and to drive signals to optical emitter 22 that responsively emits one or more beams 71 of optical radiation, typically at a predefined wavelength (described below), or a suitable range of wavelengths, depending on the application of optical module 20.

In some embodiments, optical emitter 22 is mounted on driver 33, and is connected to terminals such as bumps (shown in FIG. 4 below) configured to exchange signals between optical emitter 22 and driver 33, as will be described in detail in FIG. 4 below. The concept of optical emitter 22 mounted on driver 33 is also referred to herein as VCSEL over silicon (VoS) because the driver 33 comprises an integrated circuit whose substrate is typically made from silicon (or from any other suitable semiconductor material or compound semiconductor known in the art).

In some embodiments, transmitter 21 comprises a transmission lens assembly 30 configured to collect and direct beams 71 along a transmit axis 31 toward a target (shown for example in FIG. 5 below). Transmission lens assembly 30 comprises one or more lenses 32 (multiple lenses 32 are shown in detail in pictured examples of FIGS. 4 and 5 below), which are mounted in a lens barrel 34. Lenses 32 are configured to direct beams 71 through an exit window 36 toward the target.

Reference is now made back to FIG. 1. In some embodiments, receiver 23 comprises an optical filter 39 configured to filter beams 72 (shown in FIG. 2) received from the aforementioned target. Filter 39 is configured to screen out undesired wavelengths of the incoming light, which helps to isolate the light returning from the target into components of receiver 23 (that are described below).

In some embodiments, receiver 23 has an objective lens assembly 42 (described in detail below), and the thickness of filter 39 (e.g., about 0.21 mm along the Z-axis) is designed to match the mechanical total track length (mTTL) of receiver 23 to that of transmitter 21 along the Z-axis.

In some embodiments, filter 39 is coupled to objective lens assembly 42 before attaching assembly 42 to case 38 (and/or to the housing of module 20). In the present example, filter 39 is made from a suitable piece of glass having two opposing sides, with a bandpass filter on one side and a blocking filter on the opposite side of the piece of glass. In some embodiments, filter 39 comprises a stack of between about 20 and 24 alternating layers of hydrogenated silicon (having a high refractive index with high transmission of wavelengths between about 900 nm and 1000 nm) and SiO2 (having a low refractive index).

In the present example, the thickness of the bandpass filter is between about 4 μm and 5 μm, and the thickness of the blocking filter is between about 2 μm and 3 μm. It is noted that the thicknesses described above are provided by way of example and may be altered to any other suitable thicknesses. In some embodiments, the formation of the blocking filter in filter 39 enables reduced thickness, and yet, increased efficiency of the bandpass filter of filter 39.

In some embodiments, receiver 23 further comprises an optical sensor 24 (also referred to herein as a TOF imaging sensor), for example an array of imaging pixels implemented in an avalanche photodiode (APD), or a single-photon avalanche diode (SPAD), or an array of such photon detectors, or alternatively a detector or detector array that is capable of continuous or gated sensing.

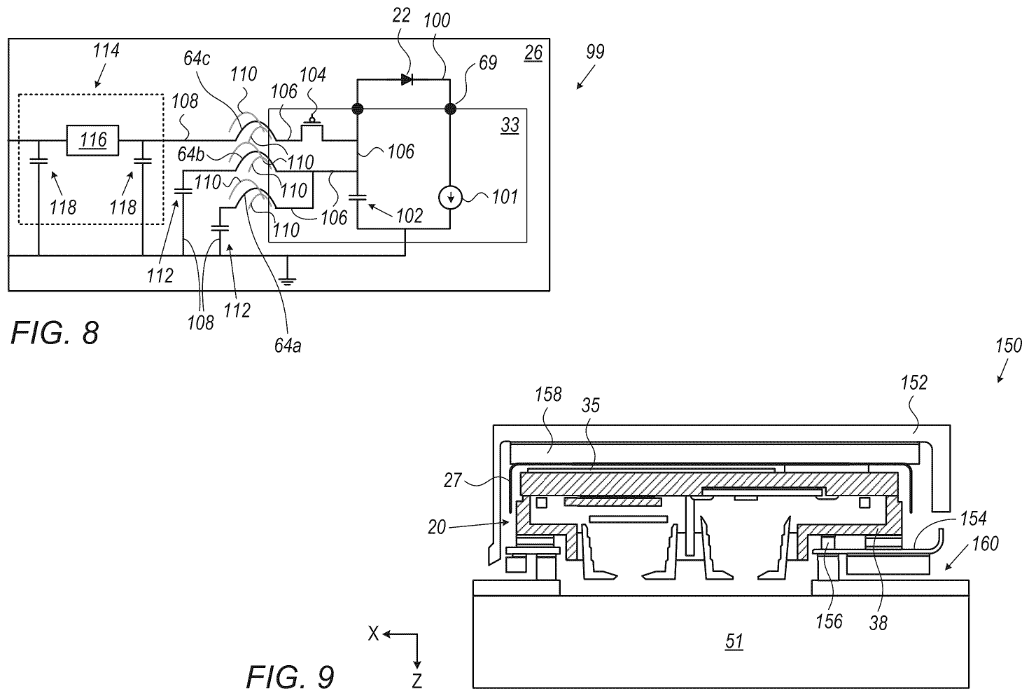

In some embodiments, receiver 23 comprises an additional optical sensor 25 having an array of imaging pixels. In the present example, the pixels of optical sensor 25 are arranged in two or more rows, but in other embodiments, the pixels of optical sensor 25 may have any other suitable arrangement (e.g., similar to that of optical sensor 24). Emitter 22 and sensors 24 and 25 are mounted on substrate 26 together with ancillary electronic components 28 and 29, respectively, such as but not limited to IC-based amplifiers, micro-capacitors (described below), control circuits, additional drivers, which are typically connected to the emitter and the sensor by electrical circuit traces (not shown), and any other suitable active and passive devices, such as but not limited to filters and capacitors that are typically mounted on or embedded within CB 35. Some of ancillary electronic components 28 are described in FIG. 8 below.

Reference is now made back to FIG. 2. In some embodiments, receiver 23 has the aforementioned objective lens assembly 42 comprising one or more lenses 43, which are mounted in a barrel 46. Lenses 43 focus the optical radiation (e.g., beam 72) reflected from the target along a receive axis 45 through an entrance window 40 of receiver 23, and impinge on optical sensor 24.

In some embodiments, module 20 comprises a case 38. In the present example, case 38 comprises a metal injection mold (MiM) case made from injection molded SUS316L, which is stainless steel containing about 18% chrome, 12% nickel, and low percentage of carbon (e.g., about 0.03%) and molybdenum.

In some embodiments, the injection molded SUS316L is coated with a layer of nickel having a thickness between about 2 μm and 5 μm, and a phosphor content between about 7% and 13% in the plated nickel layer. Case 38 is bonded to stiffener 27 using a suitable electrically conductive epoxy 16, in the present example ag epoxy, such as the CJ-722 product, supplied by Ajinomoto (1-2 Suzukicho Kawasaki-Ku Kawasaki, 210-0801 Japan). Moreover, stiffener 27 is bonded to substrate 26 using a bonding material 17, in the present example, a combination of (i) a suitable electrically conductive epoxy, e.g., ag epoxy, such as the Henkel Loctite Ablestik XCE 3111, and (ii) a suitable thermal epoxy, such as the Henkel Loctite Ablestik NCA 2350 product, both products and/or the combination thereof, are supplied by Henkel AG & Co. (KGaA 40191 Düsseldorf Germany). In other embodiments, stiffener 27 (or at least a portion thereof) may be omitted from the configuration of module 20, as described in more detail in FIG. 1 above.

In some embodiments, case 38 is further configured to serve as a shield to protect devices from electromagnetic interference (EMI) generated during the operation of module 20 and the electronic device comprising module 20. In the present example, the EMI may comprise: (i) a first EMI generated by one or more of the aforementioned ICs of module 20 (e.g., driver 33), and (ii) a second EMI generated by EMI sources external to module 20, such as but not limited to antennas of wireless communications. In such embodiments, case 38 is configured to protect: (i) devices external to module 20 from the first EMI, and (ii) the components of module 20 from the second EMI. Moreover, module 20 comprises multiple grounding elements connecting between respective multiple dedicated locations of case 38 and a common electrical ground point, such as CB 35 or any other suitable common grounding point. The grounding elements and common electrical ground point are shown and depicted in detail in FIG. 3B below.

In some embodiments, the size of module 20 along the Z-axis determines the thickness of a handheld electronic device comprising module 20. In an embodiment, in order to reduce the size of module 20 driver 33 is disposed within cavity 15 in substrate 26, and optical emitter 22 is mounted on driver 33. In the present example, a portion of lens assemblies extend out of case 38.

In some embodiments, the EMI generated within module 20 is sufficiently low to allow the lens to extend out past the case without the need to include the lens within the boundary of case 38. As will be described in FIG. 4 below, module 20 does not have a diffractive optical element to manipulate beams 71 emitted from optical emitter 22, and thereby, simplifying and reducing the z-height of module 20. As described in FIG. 1 above, the thickness of filter 39 of receiver 23 is reduced, which contributes to the overall reduction of the thickness of module 20 along the Z-axis while maintaining parity of barrels 34 and 46, and close to parity of the pupil of transmitter 21 and receiver 23. Thus, a sum of the above technical contributions reduces the thickness of module 20.

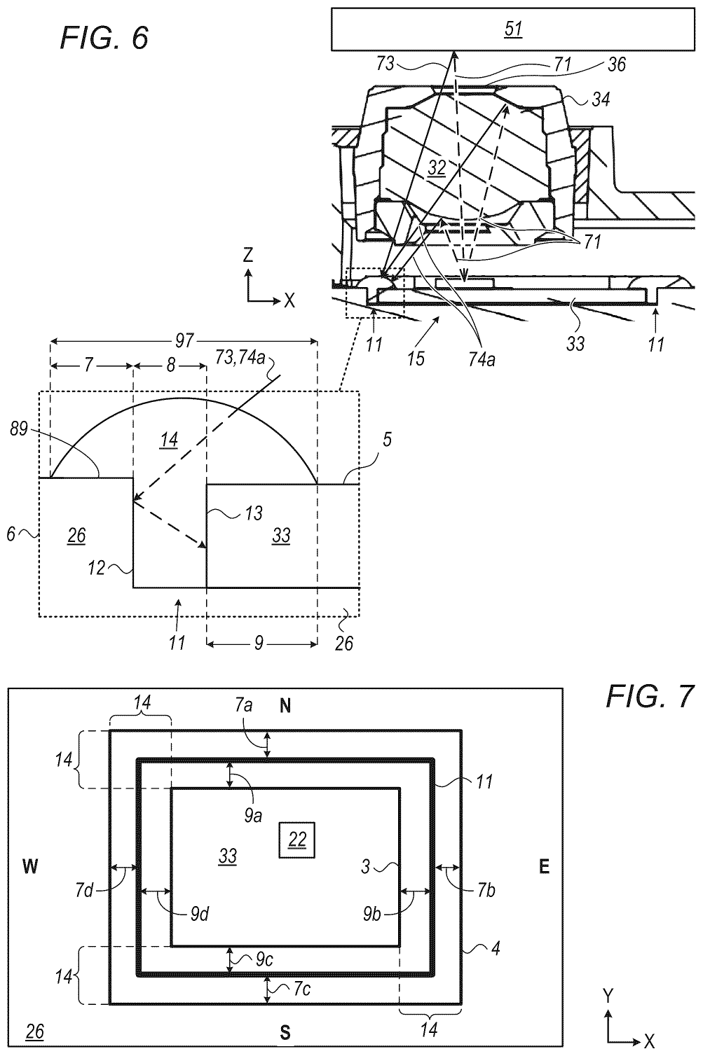

In some embodiments, a filler 14 is disposed between the edges of driver 33 and cavity 15. Filler 14 surrounds the edges of driver 33 and cavity 15 and configured to protect driver 33 from the optical radiation impinging on at least the edge of driver 33, as will be depicted in detail in FIG. 6 below.

It is noted that ToF-based depth sensing devices, such as module 20, are almost inevitably subject to stray reflections of beams 71. In the present example, the stray light comprises: (i) an internal stray light beam 74, reflected or otherwise scattered from optical surfaces within optical transmitter 21, through an opening (shown in FIGS. 3A and 3B below) in a wall 66 (also referred to herein as a barrier) within case 38, toward optical receiver 23, and (ii) an external stray light beam 73, reflected or otherwise scattered toward optical receiver 23. In the present example, beam 73 is reflected from one or both surfaces 52 and 53 of a plate 51. In the present example, plate 51 comprises glass or any other suitable transparent material, which is coupled to the outer housing (not shown) of the handheld electronic device and is configured to allow infrared (IR) light to pass while sealing module 20 against mechanical damage and moisture.

As described above, stray reflections are regarded as noise, but as described in U.S. Pat. Nos. 9,335,220 and 11,681,019, whose disclosures are incorporated herein by reference, in the ToF-based scanner the stray reflections are used intentionally in calibrating the ToF measurements. In the context of the present disclosure and in the claims, the term “calibration” refers to a verification of the accuracy of the distance measured by module 20, as will be described in more detail in FIG. 3A below.

In some embodiments, optical transmitter 21 comprises a retainer ring (RR) 55 (shown and depicted in detail in FIG. 3A below) made from polycarbonate and having an asymmetric structure. In the present implementation, RR 55 is configured to direct beam 74 toward optical sensor 24, as will be shown and described in detail in FIG. 3A below.

In some embodiments, in response to beams 72, 73 and 74 impinging on the surface of optical sensors 24 and 25, optical receiver 23 is configured to generate and output electrical signals to a processor (not shown) that may be (i) mounted within module 20, or (ii) connected to module 20, e.g., via CB 35 and connector 39. Based on the signals the processor is configured to generate a 3D image of a scene of the aforementioned target. More specifically, the processor is configured to receive, (i) a first electrical signal output by optical receiver 23 at a first time due to the internal stray light beam 74, and (ii) a second electrical signal output by optical receiver 23 at a second time due to beam reflected from the scene. The processor is configured to generate a measure of the ToF of the optical pulses of beams 71 and 72 to and from points in the scene, respectively, by calculating the difference between the respective first and second times of output of the first and second electrical signals. Examples of the target in the scene, and the images generated by optical receiver 23 are shown and described in FIG. 5 below.

Reference is now made to FIGS. 3A and 3B.

FIG. 3A is a schematic, top view of stray light beams 74, 75 and 76 directed between optical transmitter 21 and optical receiver 23 of optical module 20, in accordance with an embodiment of the invention. It is noted that beams 74 are the origin of beams 75 and 76, as will be described herein.

FIG. 3B is a schematic pictorial illustration of case 38 of optical module 20, in accordance with an embodiment of the invention.

Reference is now made to FIG. 3A. In some embodiments, wall 66 has an opening 77 to allow stray light beam 74 to pass from optical transmitter 21 to optical receiver 23. Retainer ring 55 is designed with an opening 57 to direct beam 74 toward opening 77. In the present example, RR 55 has a base shaped as a full ring, and opening 57 is above the base of RR 55 along the Z-axis. In other words, the base of RR 55 is used for aligning the position of lenses 32 (as described above), and opening 57 allows the passage of beams 74 emitted from optical emitter 22 at a predefined range of angles in the XY plane of the XYZ coordinate system. Moreover, the surfaces of RR 55 are configured to reflect the radiation of beam 74.

In some embodiments, based on the geometry and reflecting surfaces of RR 55, (i) a first portion of beam 74, referred to herein as a beam 75, passes through opening 77 and impinges on the surface of optical sensor 25, and (ii) a second portion of beam 74, referred to herein as a beam 76 (typically substantially smaller than the portion of beams 75), is deflected in wall 66 and passes through opening 77, and subsequently, impinges on the surface of optical sensor 24.

In such embodiments, the processor is configured to select at least one of beams 75 and 76 in order to perform ToF calibration (relative to beam 72 described in FIG. 2 above) without causing excessive noise in optical receiver 23. It is noted that as mentioned above, the term “calibration” refers to verification of the distance accuracy. In the present example, the arrival time of beam 75 to optical sensor 25 is compared with the arrival time of beam 72 to sensor 24. In some embodiments, based on the structure of module 20, the distance travelled by beam 75 is known and serves as a reference. In such embodiments, based on the arrival times of beams 75 and 72, the processor is configured to estimate the distance between module 20 and the target.

In the present configuration, only beam 75 is detected by optical sensor 25, and as described above, beam 75 is used as the ToF reference. Moreover, beam 76 that impinges on optical sensor 24 is harmful and may reduce the performance of module 20. It is noted that in the present disclosure, optical sensor 25 is separated from optical sensor 24, and thereby, allowing optimization of the detection of beam 75 over the detection beam 76 (which is harmful as described above).

In some embodiments, the structure of wall 66 and opening 77 is configured to reduce the level of beam 76 low while maintaining a sufficiently high level of beam 75 for performing the distance calibration. Moreover, the shape of retainer ring 55 (e.g., opening 57) aids in directing beam 75 to sensor 25.

Reference is now made to FIG. 3B. In some embodiments, case 38 has openings 58 and 59 for containing and positioning lens assemblies 30 and 42, respectively. During integration, emitter 22, driver 33, and sensor 24 are mounted on substrate 26, which is subsequently attached to case 38. This assembly is inserted into an active alignment (AA) machine. In the AA machine, lens assemblies 30 and 42 are placed into openings 58 and 59, respectively, and are attached to case 38 (e.g., using a suitable bonding layer, such as AA epoxy 65). As such, lens assemblies 30 and 42 are aligned with optical emitter 22 and optical sensor 24 along transmit axis 31 and receive axis 45, respectively.

It is noted that lens assemblies 30 and 42 are omitted from the general view of FIG. 3B for the sake of presenting wall 66 and opening 77. Wall 66 serves as a buffer between optical transmitter 21 and optical receiver 23, which are positioned at opposite sides of wall 66, and opening 77 allows passage of stray light beam 74 from optical transmitter 21 to optical receiver 23, as shown and depicted in FIG. 3A above.

In some embodiments, case 38 has multiple dedicated locations for disposing multiple electrically conductive grounding elements 62 (shown in an inset 61 below), respectively. In the present example, optical module 20 has a rectangular shape (approximately), As such, case 38 has four dedicated locations 60a, 60b, 60c and 60d at the four apexes or corners of case 38, for disposing four grounding elements, respectively.

In some embodiments, grounding element 62 is soldered to substrate 26, in the present example, the soldering occurs at protrusions 79 (also referred to herein as teeth). This solder electrically connects between case 38 and substrate 26 for grounding purposes. The broad, flat, and relatively large connection area between protrusions 79 and substrate 26 are advantageous over thinner connection to easily move charge. As such, grounding elements 62 are configured to reduce the impendence and serve as an escape route to ground, to any undesired charge build up on case 38. It is noted that if unwanted charge builds up, the surface of case 38 may undesirably radiate an electrical field that may interfere with the operation of neighboring devices.

It is noted that in order to reduce the EMI and/or to obtain a uniform distribution of the charge at least at a predefined range of frequencies, the shape of optical module 20 determines the number of dedicated locations 60 and the properties (e.g., shape and materials) of grounding elements 62. In the present example, each of grounding elements 62 is shaped as two teeth (e.g., a rectangle with two protrusions extending from a facet of the rectangle), as shown in inset 61 below, but in other embodiments, at least one of grounding elements 62 may have any other suitable shape. In a general example configuration, both optical module 20 and case 38 may have a polygonal shape, and a dedicated location 60 at some of or all of the apexes of the polygonal shape. In another example, at least one of the dedicated locations 60 may be positioned within a facet between two apexes.

In some embodiments, conductive material (not shown) is disposed over the upper surface of case 38 (which is facing plate 51, as shown in FIG. 2 above), so as to ground undesired charge buildup on case 38 to the chassis of the electronic device (both shown in FIG. 9 below).

Reference is now made to inset 61. In some embodiments, grounding element 62 (also referred to herein as a grounding castellation for being located at the corners of module 20 having a castle-like shape) is assembled at location 60a for electrically connecting between case 38 and substrate 26.

In the present configuration, substrate 26 is electrically connected to CB 35 that serves as a common electrical ground point. In some embodiments, CB 35 may be connected to another grounding point located outside module 20 and/or to another grounding located in or connected to stiffener 27.

Reference is now made to an inset 63 showing the interfaces between case 38 (substrate 26, not shown), and stiffener 27. It is noted that inset 63 also shows parts of lens assemblies 30 and 42, which are intentionally omitted from the general view of FIG. 3B in order to show the shape of wall 66 and opening 77.

In some embodiments, electrically conductive epoxy 16 (that appears in a dashed line for being disposed between case 38 and stiffener 27) is disposed along the X- and Y-axes at the edges of module 20, as described in detail in FIG. 2 above.

In other embodiments, electrically conductive epoxy 16 may be omitted from the configuration of module 20, and any other suitable technique may be applied for producing an electrically conductive coupling between case 38 and stiffener 27, such as a spring contact or push contact (both not shown) for coupling between case 38 and stiffener 27.

This particular configuration of case 38, locations 60 and grounding elements 62 is shown by way of example, in order to illustrate certain problems that are addressed by embodiments of the present invention and to demonstrate the application of these embodiments in enhancing the performance of such an optoelectronic assembly (e.g., module 20). Embodiments of the present invention, however, are by no means limited to this specific sort of example configuration and shape of case 38 and the other aforementioned components, and the principles described herein may similarly be applied to other sorts of optoelectronic assemblies having other suitable shapes.

FIG. 4 is a schematic sectional view of optical transmitter 21 of optical module 20, in accordance with an embodiment of the invention.

In some embodiments, the depth of cavity 15 along the Z-axis is approximately similar to the combined thickness, along the Z-axis, of (i) driver 33, (ii) a bonding layer 85 disposed between a lower surface 80 of driver 33 and a lower surface 92 of cavity 15, and (iii) bumps 69 shown in an inset 86. In other embodiments, an upper surface 5 of driver 33 and an upper surface 89 of substrate 26 are flush, so that the upper surface of bumps 69 is proud (e.g., located higher along the Z-axis) compared to the outer surface 89 of substrate 26.

Based on the embodiments described above, upper surface 5 of driver 33 is flush with upper surface 89 of substrate 26. In the present example, a mechanical total track length (mTTL) 70a is defined between the upper surface (along the Z-axis) of emitter 22 and the upper surface of barrel 34, which is typically flush with opening 36. Moreover, an optical total track length (oTTL) 70b is defined between the upper surface of emitter 22 (along the Z-axis) and the upper surface of transmission lens assembly 30 (in the present example, the upper surface of lens 32a).

It is noted that disposing driver 33 within cavity 15 reduces the total size (e.g., height) of optical transmitter 21 along the Z-axis, and thereby, reduces the thickness of the handheld electronic device (along the Z-axis), as described above.

In some embodiments, a bonding layer 90 (e.g., any suitable type of thermal epoxy) is disposed between case 38 and surface 89, and is configured to bond between substrate 26 and case 38. Driver 33 is electrically connected to substrate 26 via wire bonding (WB) 64. Substrate 26 has electrical pathways which conduct current down to CB 35. Substrate 26 has pads 98 on the bottom side which are electrically connected to CB 35 via an anisotropic conductive film (ACF) 97.

In some embodiments, bumps 69 (shown in inset 86) are configured to electrically connect between driver 33 and optical emitter 22. As such, driver side wire bonds shown in FIG. 8 below, are configured to serve as a coplanar ground in optical transmitter 21 of module 20.

In some embodiments, the use of bumps 69 (e.g., instead of wire bonding or another technique) reduces the EMI that could have been generated in case driver 33 and optical emitter 22 would have been electrically connected via wire bonding. In other words, the VCSEL over Silicon (VoS) configuration having optical emitter 22 connected to driver 33 via bumps 69, reduces the EMI generated by driver 33 and optical emitter 22. As a result of the reduced EMI, a portion of lens assembly 30 could be extended out of case 38 with sufficiently low EMI emission out of optical transmitter 21 that does not interfere with the operation of components of the electronic device that are located in proximity to module 20. Moreover, as shown in FIG. 2 above, a portion of lens assembly 42 (of optical receiver 23) also extends out of case 38, such that in the present example, exit windows 36 and 40 are flush along the Z-axis with some tolerance on the flushness. It is noted that in other embodiments of the invention, exit windows 36 and 40 may not be flush with one another along the Z-axis. But the offset between windows 36 and 40 along the Z-axis must be sufficiently small in order to prevent interference with the light beam cones, which may result in reduced field of view (FOV) especially at longer distance.

In some embodiments, lens assembly 30 comprises an extension 81 in the XY plane, and optical transmitter 21 comprises a bonding layer 65 configured to bond between lens assembly 30 (including extension 81) and case 38.

Reference is now made to an inset 67 showing lens assembly 30 excluding extension 81 depicted above. In some embodiments, lens assembly 30 comprises barrel 34 that at least partially encapsulates (i) retainer ring 55, (ii) lenses 32a, 32b and 32c stacked on one another over retainer ring 55, and other components described herein. As described in FIGS. 2, 3A and 3B above, ToF-based depth sensing devices, such as module 20, are almost inevitably subject to stray reflections of beams 71, such as stray light beam 74. Moreover, module 20 requires a reference signal, which is used as time zero of the ToF for performing accurate depth sensing. As such, it is important to control both the intensity and the reflection angle of stray light beam 74, to obtain suitable reference stray pixels without causing excess stray light in the imaging pixels. In some cases, the reflections inside optical transmitter 21 may not be able to obtain the required level of intensity of stray light beam 74.

In some embodiments, lens assembly 30 comprises one or more layers 168, also referred to herein as anti-reflective coating (ARC), which are formed on the lower surface of lens 32c. In the present example, layers 168 comprise a stack of two pairs of alternating layers of (i) titanium oxide (TiO), and (ii) silicon oxide (SiO2). The total thickness of layers 168 is typically between about 300 nm and 400 nm. As such, in response to directing beams 71 from optical emitter 22 toward lens assembly 30, the stack of layers 168 is configured to selectively reflect stray light beam 74 at predefined angles toward optical sensor 24 (e.g., via opening 77 shown in FIGS. 3A and 3B above), so as to obtain the required level of intensity of stray light beam 74 impinging on the surface of optical sensor 24 (shown and described in detail in FIG. 3A above).

Reference is now made back to the general view of FIG. 4. It is noted that other sorts of optical transmitters (i.e., having a different configuration than that of optical transmitter 21) may comprise one or more diffractive optical elements (DOEs) configured to multiply each of beams 71, and thereby, to increase the number of spots intended to impinge of the target in the scene. Such DOEs, however, increase the mTTL, and thereby, undesirably increase the total height of optical transmitter 21.

In some embodiments, in the example of optical transmitter 21 of module 20, the processor described in FIGS. 1 and 2 above is configured to generate the 3D image based on the number of spots described above, i.e., without multiplying or otherwise increasing the number of beams 71.

Additionally, or alternatively, the quality of lens assembly 30 may be improved by increasing the size and or number of lenses 32. This configuration may result in a slight increase of lens assembly 30 along the Z-axis, which is compensated by reducing the need for the aforementioned DOE and results in a smaller mTTL compared to that of a lens assembly having a lower quality of lenses and a DOE.

Reference is now made back to inset 67. In some embodiments, lens assembly 30 comprises at least a lens aperture (LA) 88 (shown as a dashed circle). In the present example, LA 88 is mounted between lenses 32a and 32b, but in other embodiments, lens assembly 30 may comprise any other suitable number of such apertures that are disposed between one or more pairs of lenses 32 and/or at any other suitable position within lens assembly 30. The functionality of LA 88 is depicted herein.

Reference is not made to an inset 68, which is a sectional view of the beams within lens assembly 30, and for showing the functionality of LA 88. As depicted in FIG. 2 above, some external stray light beams 73 are reflected or otherwise scattered from surfaces 52 and 53 of plate 51 (typically made from glass or another transparent material) toward optical receiver 23. In some cases, external stray light beams 73a and 73b among the external stray light beams 73 are scattered back from plate 51 toward optical transmitter 21, pass back through flanges (not shown) of lenses 32, and subsequently, reflect off axis 31 and may impinge on the surface of optical sensor 24.

In some embodiments, LA 88 is made from any suitable material opaque to the wavelengths of beams 71 and 73 (e.g., between about 900 nm and 1000 nm and has a ring shape or a horus shape, with an inner diameter 82 and an outer diameter 84. In the present example, LA 88 is configured to block beams 73a and to pass beams 73b propagating back toward optical emitter 22 and remaining within optical transmitter 21.

In some embodiments, the position of LA 88, and the size of diameter 82 (particularly) and diameter 84, determine which backscattered beams 73 are blocked, and thereby, reduce the level of noise in the 3D image acquired by optical module 20.

Reference is now made back to FIG. 2. Additionally, or alternatively to LA 88, one or more lens apertures (similar to or different from LA 88) may be implemented at one or more suitable positions within lens assembly 42 of optical receiver 23 (e.g., between lenses 43), so as to reduce the number of beams 73 reaching the surface of optical sensor 24 and increasing the noise level in the 3D image.

Reference is now made back to FIG. 4. It is noted that (i) the thickness of each of the components and the bonding layers, which are stacked along the Z-axis between exit window 36 and bonding layer 85, and (ii) the tilt angle of some of the components within the stack, are controlled within predefined respective tolerances, so as to obtain the specified optical properties and size (along the Z-axis and in the XY plane) of optical transmitter 21.

This particular configuration of optical transmitter 21 is shown by way of example, in order to illustrate certain problems that are addressed by embodiments of the present invention and to demonstrate the application of these embodiments in enhancing the performance of such an optical transmitter. Embodiments of the present invention, however, are by no means limited to this specific sort of example configuration of optical transmitter 21, and the principles described herein may similarly be applied to other sorts of optical transmitters implemented in other sorts of optical modules.

FIG. 5 is a schematic sectional view of optical modules 20a and 20b, in accordance with an embodiment of the invention. Optical modules 20a and 20b represent different groups of optical modules having approximately the same structure and properties of module 20 of FIGS. 1 and 2 above. In the present example, modules 20a and 20b are controlled separately for emitting beams 71 toward the target in a scene 93, as will be described in detail hereinbelow.

In some embodiments, optical emitter 22 comprises an array of VCSELs (e.g., optical emitters 22a and 22b) configured to emit multiple beams 71, which are directed by lens assembly 30 to impinge as multiple respective spots on objects of scene 93 as described in FIGS. 1 and 2 above. The VCSELs of optical emitters 22a and 22b are arranged in multiple banks, shown in modules 20a and 20b, respectively. Each bank is controlled separately and receives electrical signals from driver 33 to emit beams 71, as described in detail in FIGS. 1, 2, and 4 above. In other words, the banks are groups of emitters, which can be turned on and off separately. In the present example, the optical emitter comprises about eight banks, which are configured to produce between about 50 and 300 spots on the surface(s) of the scene.

In other embodiments, optical emitter 22 may comprise any other suitable number of emitters (smaller than 50 or larger than 300) arranged in any other suitable number of banks.

In some embodiments, the arrangement of the VCSELS of optical emitters 22a and 22b in multiple banks mitigates the external stray light as will be described herein. As described in FIGS. 1 and 2 above, beams 72 are received from scene 93 by lens assembly 42, and are directed into optical sensors 24a and 24b of modules 20a and 20b, respectively.

Reference is now made to module 20a. In the present example, beams 72 are reflected from the scene and impinge on a section 10a of the surface of optical sensor 24a. But the bank comprising module 20a is prone to noise from external stray light beams 73c, which are reflected from surfaces 52 and/or 53 of plate 51 and impinge on a section 10b (different from section 10a) of the surface of optical sensor 24a. Based on the signals received from optical sensor 24a, the processor (described in FIGS. 1 and 2 above) is configured to generate a 3D image 94a. In the present example, (i) markers 95a are indicative of locations in image 94a generated based on spots of beam 72 reflected from scene 93, and (ii) markers 96 are indicative of locations in image 94a generated based on spots of external stray beam 73c reflected from plate 51.

It is noted that even though optical 24a receives both (desired) beams 72 and (undesired) beams 73, the processor is configured to generate image 94a having the partitioning of markers 95a and 96 in different sections of image 94a (corresponding to sections 10a and 10b of optical sensor 24a, respectively).

Reference is now made to module 20b. In the present example, beams 72 are reflected from the scene and impinge on the surface of optical sensor 24b, and external stray light beams 73d are reflected from plate 51, but are not entered into lens assembly 42. As such, the processor is configured to generate a 3D image 94b, which has markers 95b indicative of locations in image 94b generated based on spots of beam 72 reflected from scene 93.

In the present example, the signal to noise ratio (SNR) in 3D image 94a, which is generated using module 20a, is smaller than that in 3D image 94b, which is generated using module 20b.

In some embodiments, based on images 94a and 94b, the processor is configured to reduce the level of noise generated by the external stray light, e.g., by presenting image 94b to a user, or using any suitable filtering in (i) the acquisition of image 94a and/or (ii) the processing of at least the section having markers 96 in image 94a, so as to remove the noise associate with the external stray light for the 3D image presented to the user (or used in the background for any other application).

It is noted that the orientation of the handheld electronic device containing modules 20a and 20b may be altered with time (e.g., due to relative movement between the handheld electronic device and scene 93, external light sources and other factors affecting the SNR). In some embodiments, the processor continuously monitors the SNR in all the 3D images received from the optical modules 20 of the handheld electronic device, and may alter the image acquisition and/or image processing applied to the optical modules 20 and the 3D images 94, responsively to the SNR in each of the 3D images 94.

Additionally, or alternatively, based on the SNR in 3D images 94a and 94b, the processor is configured to control module 20b to direct beams 71 toward scene 93, and at the same time, control module 20a not to emit beams 71 (e.g., turn off module 20a).

FIG. 6 is a schematic sectional view of optical transmitter 21, in accordance with another embodiment of the invention.

In some embodiments, driver 33 is disposed within cavity 15 having any suitable depth between about 10 μm and 400 μm, so as to reduce the size of optical transmitter 21 (and optical module 20) along the Z-axis, as described in the example of FIG. 4 above.

In some embodiments, driver 33 comprises any suitable driver, which may be an off-the-shelf driver or a customized driver (in the present example).

In some embodiments, the size of cavity 15 along the X- and Y-axes is determined to be larger than that of driver 33 so as to leave a trench 11 therebetween after disposing driver 33 within cavity 15. In this configuration, trench 11 surrounds the edges of driver 33. As described in FIGS. 2 and 5 above, several types of internal and external stray light beams are formed in response to the generation of beams 71. In the present example, internal stray light beams 74a are reflected from any reflective surface within optical transmitter 21, such as but not limited to lens 32 and lens barrel 34 described in FIGS. 2 and 4 above. Moreover, external stray light beams 73 are reflected from the surfaces of plate 51, also known as the back glass of optical module 20, as described in detail in FIGS. 2 and 5 above.

Reference is now made to an inset 6 showing trench 11 having a width 8, and other elements of module 20 that are surrounding trench 11.

In some embodiments, driver 33 is not packaged and comprises, inter alia, analog, and digital transistors configured to regulate the level of driving current applied to optical emitter 22 for generating beams 71.

In some cases, the radiation of the internal and external stray light beams 73 and 74a may impinge directly on a sidewall 13 of driver 33, or after being reflected from a sidewall 12 of cavity 15. It is noted that in response to impinging on sidewall 13, the radiation of the internal and external stray light beams 73 and 74a may induce excess charge carriers (e.g., electrons and/or holes) that may disrupt the operation of the analog and digital transistors. This disruption may cause uncontrolled flux and intensity of beams 71 that are emitted from optical emitter 22, which may result in (i) safety issues cause by excess beam radiation, and (ii) reduced quality of the 3D image generated by module 20, in case of insufficient flux and/or intensity of beams 71. As shown in inset 6, beams 73 and 74a are illustrated in a dashed line, because the intensity of beams 73 and 74a is being attenuated by filler 14, in accordance with embodiments of the invention that are described herein.

In some embodiments, filler 14 is dispensed (i) into trench 11, (ii) over an edge section 7 of upper surface 89 of substrate 26, and (iii) over an edge section 9 of an upper surface 5 of driver 33. In the present example, filler 14 comprises a suitable type of resin adapted to attenuate the intensity of the wavelength (e.g., between about 900 nm and 1000 nm) of beams 73 and 74a.

In the present example, filler 14 comprises a SONA0047E product, supplied by Namics Corporation, (3993 Nigorikawa, Kita-ku, Niigata City, Niigata Prefecture 950-3131, Japan). Filler 14 is dispensed using a glob top technique, or any other suitable dispensing technique. In some embodiments, upper surface 5 sidewall 13 and edge section 9 are typically protected against the radiation of the internal and external stray light beams, for example, by disposing on surface 5 any suitable type of one or more protective layers, which are formed using any suitable sputtering, plating, or chemical vapor deposition (CVD) techniques.

In some embodiments, the material selection and the dispensing process of filler 14 control several parameters of filler 14. For example, the parameters comprise the volume, temperature and viscosity of filler 14, so as to: (i) completely fill trench (by sufficiently low viscosity), and at the same time (ii) control (a) the size of filler 14 along the X- and Y-axes for covering the predefined size of sections 7 and 9, and (b) the thickness of filler along the Z-axis in order to fully attenuate the intensity of the internal and external stray light beams. For example, in response to exceeding the specified level of at least one of the temperature, the viscosity and the volume of filler 14, the coverage of filler 14 may undesirably exceed the area of at least one of sections 7 and 9. Alternatively, insufficient volume of dispensed filler 14 may result in insufficient attenuation of the intensity of the stray light beams.

In the present example, the size of sections 7 and 9 along the X- and Y-axes is similar, about 100 μm. In other embodiments, at least one of sections 7 and 9 may have a different size, depending on the architecture of other components of optical transmitter 21, such as but not limited to the interconnects (e.g., WB 64 shown in FIG. 4 above) and ancillary electronic components 28 (shown in FIG. 1 above) surrounding cavity 15 and driver 33.

FIG. 7 is a schematic top view of substrate 26, driver 33, and optical emitter 22 of optical transmitter 21, in accordance with an embodiment of the invention.

In the present example, an inner frame 3 defines the edges of section 7, an outer frame 4 defines the edges of section 9, and trench 11 appears in a frame located between frames 3 and 4. As such, filler 14 is disposed in the area confined between frames 3 and 4 in the XY plane of the XYZ coordinate system. More specifically, filler 14 is disposed on: (i) surface 5 of driver 33, (ii) surface 89 of substrate 26, and (iii) within trench 11.

In some embodiments, the size of at least one of sections 7 and 9 may be altered subject to constraints related to the design of additional components of optical transmitter 21. In the present example, substrate 26 has four sides, referred to herein as a North side (N) having sections 7a and 9a coated with filler 14, East side (E) having sections 7b and 9b coated with filler 14, South side(S) having sections 7c and 9d coated with filler 14, and West side (W) having sections 7d and 9d coated with filler 14.

In some embodiments, the size of sections 7a, 9a, 7c and 9c is typically similar along the Y-axis, and size of sections 7b, 9b, 7d and 9d is typically similar along the X-axis, in the present example all the above sizes equal about 100 μm, as described in FIG. 6 above.

In alternative embodiments, the size of at least one of the sections 7a-7d and 9a-9d may be altered while still maintaining effective light blocking. For example, the size of section 7d may be slightly altered, or controlled more tightly to prevent resin bleeding out (RBO) (e.g., spreading out of frame 4), in case ancillary electronic components 28 are positioned at the west side in close proximity to frame 4. In another example, the size of section 7a is tightly controlled (or even slightly reduced) to prevent undesired mixing between filler 14 and a bonding layer (not shown) disposed at the north side for gluing between substrate 26 and a housing (not shown) of the aforementioned handheld electronic device.

FIG. 8 is a schematic illustration of a driver circuitry 99 of optical transmitter 21, in accordance with an embodiment of the invention.

In some embodiments, driver circuitry 99 comprises driver 33 and optical emitter 22, which is connected to driver via bumps 69 and electrical traces 106 implemented in driver 33 as electrical circuit 100.

In some embodiments, driver 33 comprises current supply circuitry 101 configured to drive current to electrical circuit 100. Driver 33 further comprises a capacitor 102, which is configured to accumulate the current supplied by current supply circuitry 101 and to deliver driving pulses to optical emitter 22 via bumps 69 and electrical traces 106.

In some embodiments, driver circuitry 99 comprises wire bonds (WBs) 64, in the present example, WBs 64a, 64b and 64c, configured to electrically connect between driver 33 and substrate 26. Driver circuitry 99 further comprises pairs of WBs 110, located at the sides of WBs 64a, 64b and 64c, and configured to serve as coplanar ground. In the present example, three pairs of WBs 110 flank the power lines implemented in WBs 64a, 64b and 64c, respectively. WBs 110 are configured to serve as electrical shields and to reduce the loop inductance in driver circuitry 99.

In some embodiments, substrate 26 has electrical pathways, such as but not limited to electrical traces 108 configured to conduct the electrical current between driver 33 and CB 35 via WBs 64a, 64b and 64c. It is noted that some of electrical traces 108 may have a length larger than about 400 μm, so as to conduct the current along the thickness (in the Z-axis) of substrate 26, and between driver 33 and CB 35.

In some embodiments, driver circuitry 99 comprises capacitors 112 connected to traces 108, and a pi filter 114 surrounded by a virtual dashed line frame for the sake of presentation.

In some embodiments, pi filter 114 comprises a ferrite bead 116, and two capacitors 118, which are electrically connected to CB 35 via the power supply line of driver 33, and via ACF 97 and pads 98 shown in FIG. 2 above.

In some embodiments, pi filter 114 is configured to suppress peaks of high frequency switching noise (e.g., a frequency of about 2.5 GHZ) of the power supply line of driver 33. It is noted that the power supply line of driver 33 runs through substrate 26, CB 35, and other areas within the handheld electronic device. As such, any high-frequency noise on the power line may spread as EMI within module 20, as well as within the other areas of the handheld electronic device.

In some embodiments, ferrite bead 116 comprises electrical conductors surrounded by ferrite, which is a magnetic material (ceramic material of iron oxide Fe2O3). Ferrite bead 116 is configured to attenuate the aforementioned high frequency signals, and dissipate them in the form of heat.

In some embodiments, driver 33 comprises at least a transistor 104, which is configured to switch on and off the connection between electrical circuit 100 and pi filter 114.

In some embodiments, capacitors 112 and pi filter 114 are implemented in ancillary electronic components 28 shown in FIG. 1 above.

In some embodiments, driver circuitry 99 is electrically connected to CB 35 via the power supply line of driver 33, and via ACF 97 and pads 98 that are shown and described in FIG. 2 above.

In the present implementation, WBs 64a and 64b are configured to conduct the power supply to driver 33, WB 64c connects between driver 33 and pi filter 114.

FIG. 9 is a sectional view of module 20 integrated in a handheld electronic device 150, in accordance with an embodiment of the invention. Note that device 150 is presented by way of example, and in other embodiments, module 20 may implemented in any other suitable types of handheld electronic is devices configuration different than that of device 150. Moreover, note that in the example of FIG. 9, module 20 is flipped (i.e., upside down).

In some embodiments, device 150 comprises a chassis 152 that serves, inter alia, for grounding EMI, and an electrically insulating cowling foam 158 coupling between chassis 152 and stiffener 27 of module 20.

In some embodiments, device 150 comprises a cowling 154 that serves as a grounding path to the charge trapped on device 150 and module 20, and an electrically conductive foam 156 configured to bond between case 38 and cowling 154 for grounding the trapped charge.

In some embodiments, device 150 comprises a shim 160 configured to mechanically support plate 51, and foam 156 disposed between cowling 154 and shim 160. Plate 51 is configured to seal the components of module 20 from moisture, particle and other sorts of foreign material that may undesirably be disposed on any of the components of module 20.

The configuration of device 150 is provided by way of example and may comprise additional components and bonding layers, such as an electrically insulating pressure sensitive adhesive (PSA) disposed between components, and other suitable types of components and layers, which are typically used for encapsulating module 20 and for integrating module 20 into device 150.

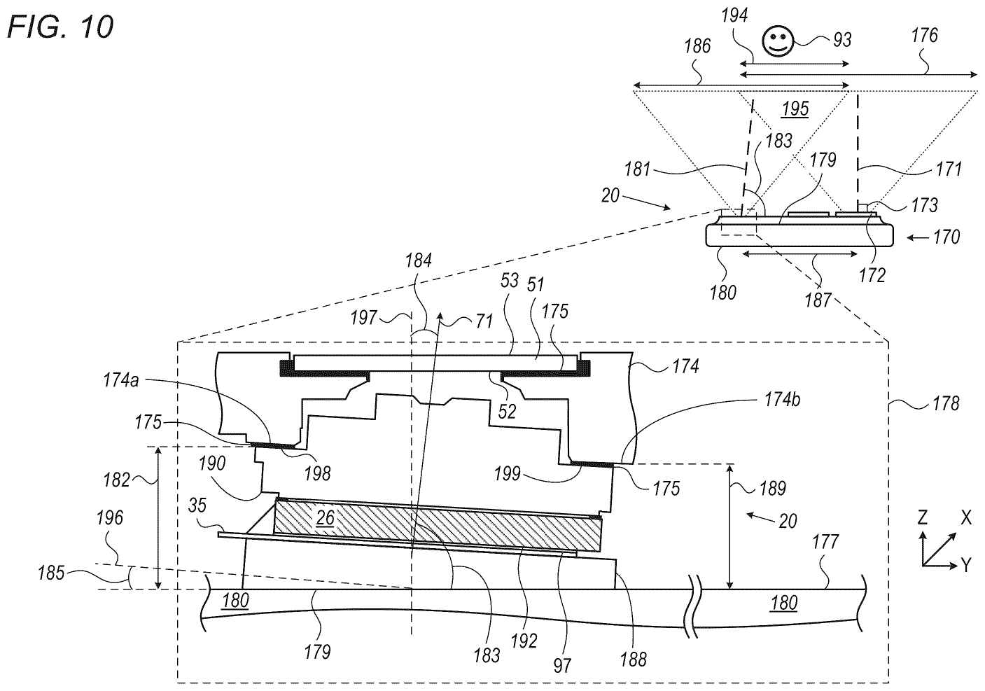

FIG. 10 is a side view of module 20 integrated in a handheld electronic device 170, in accordance with another embodiment of the invention. More specifically, the side view is perpendicular to the Y-axis, whereas in the present example, module 20 is tilted approximately 30 about the Y-axis.

In some embodiments, electronic device 170 (also referred to herein as a device, for brevity) comprises (i) a chassis 180 having an outer surface 179, also referred to herein as a plain of chassis 180, and (ii) one or more cameras, such as a camera 172, which is coupled with the chassis 180 and configured to acquire one or more two-dimensional (2D) images of scene 93. The image(s) produced by camera 172 have a field-of-view (FOV) 176 orthogonal to an axis 171 directed at an angle 173 relative to the plain of chassis 180. In the present example, angle 173 comprises a right angle.

In some embodiments, module 20 is disposed in electronic device 170 at a predefined distance 187 from camera 172. Module 20 comprises optical transmitter 21 and optical receiver 23, whose structures and functionality are described in detail, for example, in FIGS. 1, 2, 4 and 5 above. Based on the example of module 20b shown FIG. 5 above, in response to directing beams 71 toward scene 93, module 20 is configured to generate a signal indicative of a three-dimensional (3D) image of scene 93, based on the reflection of light beams 72 from scene 93. In some embodiments, the processor (described in FIGS. 1 and 2 above) is configured to generate the 3D image having a FOV 186.

It is noted that an increase in the size of distance 187 between camera 172 and module 20, reduces a size 194 an overlap 195 between FOV 176 (of the 2D image produced by camera 172) and FOV 186 (of the 3D image produced by module 20). In some embodiments, module 20 is configured to direct beams 71 toward scene 93, at an angle 183 (e.g., an acute angle) relative to outer surface 179 (i.e., the plain of chassis 180) of device 170, so as to produce FOV 186. It is noted that beams 71 are parallel to an axis 181 that is orthogonal to FOV 186 of scene 93, which is produced by module 20. In some embodiments, right angle 173 is different from acute angle 183, so that angles 173 and 183 are tilted toward one another to increase (the size 194 of) overlap 195 between FOVs 176 and 186. It is noted that a larger overlap 195 between FOVs 176 and 186 increases the quality of the 2D and 3D (and optionally a combination thereof) produced by electronic device 170.

Reference is now made to an inset 178 showing a side view of module 20 coupled with chassis 180 in accordance with an embodiment of the present disclosure. In some embodiments, device 170 comprises a base plate 188, which is slanted relative to chassis 180 and having an axis 196 inclined relative to surface 179. Moreover, (i) substrate 26 (having optical transmitter 21 and optical receiver 23 mounted thereon as described above), (ii) CB 35, and (iii) ACF 97 disposed between substrate 26 and CB 35 (as also described in FIG. 4 above), are mounted on base plate 188. In this configuration, both substrate 26 and CB 35 are also slanted relative to surface 179 of chassis 180.

In some embodiments, base plate 188 and chassis 180 may be fabricated as different parts and cowlings, and subsequently, being coupled together using a suitable glue or shim. In other embodiments, base plate 188 and chassis 180 may be fabricated together as a single continuous piece (e.g., using a suitable injection mold or using any other suitable fabrication technique). Moreover, base plate 188 may comprise multiple parts assembled together using a suitable glue or shim or may comprise a single piece having the shape of a trapezoid or a wedge.

In the present example, base plate 188 and axis 196 are slanted at an angle 185 relative to the plain of chassis 180, e.g., relative to outer surface 179 of chassis 180. In some embodiments, beams 71 that are approximately parallel with axis 181 (as described above), are directed at an angle 184 relative to a normal 197 to outer surface. It is noted the beams 71 have variations and angle 184 refers to the average angle between beams 71 and normal 197. Moreover, in the present example, the sum of angles 183 and 184 equals approximately a right angle (900) subject to minor angular variations. In the present example, one or more of the cameras, such as camera 172, are mounted on a section 177 of chassis 180, which is extended from the section of chassis 180 having base plate 188 and module 20 mounted thereon. In this example, angles 184 and 185 are approximately similar to one another and are between about 10 and 100, and in some cases between about 20 and 40. It is noted that the size of angles 184 and 185 depends, inter alia, on (i) size 187 between camera 172 and module 20, and (ii) the application of imaging scene 93.

In the present example, module 20 is mounted on base plate 188 and camera 172 is mounted directly on chassis 180 to obtain the tilting of axes 171 and 181 toward one another. In alternative embodiments, the tilting of axes 171 and 181 toward one another may be obtained by mounting (i) camera 172 on base plate 88, and (ii) module 20 directly on chassis 180 or using any other suitable arrangement to obtain the tilting of axes 171 and 181 toward one another.

In some embodiments, module 20 comprises a housing 190 disposed on substrate 26 and configured to contain optical transmitter 21 and the optical receiver 23. In the present example, housing 190, which is disposed on substrate 26, and therefore, housing 190 is also slanted relative to outer surface 179. In this example, housing 190 has (i) a first side 198 located at a distance 182 from outer surface 179 of chassis 180, and (ii) a second side 199 located at a distance 189 from outer surface 179 of chassis 180. In the present example, distance 182 is greater than distance 189.

In some embodiments, electronic device 170 comprises a housing 174, which has an asymmetric shape and is disposed on housing 190. Housing 174 comprises (i) a first section 174a disposed on the first side 198 of housing 190 and is located approximately at distance 182 from outer surface 179 of the plain of chassis 180, and (ii) a second section 174b disposed on side 199 of housing 190 and is located approximately at distance 189 from outer surface 179 of the plain of chassis 180. It is noted that distance 189 is different from (e.g., less than) distance 182. In some embodiments, electronic device 170 comprises adhesive layers 175 disposed (i) between section 174a and side 198, and (ii) between section 174b and side 199. Adhesive layers 175 are configured to couple between housings 174 and 190 and have a thickness between about 100 μm and 300 μm, so that (i) both side 198 and section 174a are located approximately at distance 182 from surface 179, and (ii) both side 199 and section 174b are located approximately at distance 188 from surface 179.

In some embodiments, housing 174 is configured to hold plate 51 (shown and described for example in FIG. 2 above), which is configured to seal at least one of and typically both optical transmitter 21 and the optical receiver 23 of module 20 (also referred to hereinabove as the optoelectronic assembly or as an optoelectronic device). Plate 51 is coupled to housing 174 using any suitable type of adhesive layer(s), such as but not limited to adhesive layers 175 described above. In the present example, beams 71 are directed from optical transmitter 21 through window 36 (shown and described in detail in FIG. 2 above) and through transparent plate 51. Similarly, as shown for example in FIG. 2 above, beams 72 and 73 enter into optical receiver 23 through transparent plate 51 and window 40. In such embodiments, plate 51 is configured to seal the components of module 20 from moisture, particle and other sorts of foreign material that may undesirably be landing or formed on any of the components of module 20, and thereby, may interfere with the operation of module 20.

In some embodiments, plate 51 has (i) surface 52, also referred to herein as an inner surface, which is facing optical transmitter 21 and optical receiver 23 (and a gap of air or another material between (a) the components of module 20, and (b) housing 174 and/or plate 51, and (ii) surface 53, also referred to herein as an outer surface, which is typically opposite surface 52 and is typically (but not necessarily) parallel to surface 52. In some embodiments, the asymmetric shape of housing 174 is configured to compensate for the slanted base plate 188, substrate 26 and housing 190, so as to position at least one of and typically both surfaces 52 and 53 in parallel with outer surface 179 of the plain of chassis 180.

In other embodiments, instead of tilting the entire structure of module 20, tilting beams 71 at angle 184 may be carried out using other techniques. For example, substrate 26 and housing 190 may be disposed directly on surface 179, so that a surface 192 of substrate 26 may be parallel to the plain (e.g., surface 179) of chassis 180. In such embodiments, housing 190 is configured to contain (i) optical transmitter 21 having transmit axis 31, and optical receiver 23 having a receive axis 45 (all shown in FIG. 2 above), and at least one of transmit axis 31 and receive axis 45 is tilted to be parallel with axis 181. This arrangement also increases the size 194 of overlap 195.

Additionally, or alternatively, the increased size 194 of overlap 195 may be obtained without tilting beams 71, (e.g., directing beams 71 orthogonal to outer surface 179, and/or having module 20 and surface 192 parallel with outer surface 179), for example, (i) by increasing the width of one or both lenses 32 and 43 of optical transmitter 21 and optical receiver 23, and/or (ii) by reducing the distance 187 between camera 172 and module 20.

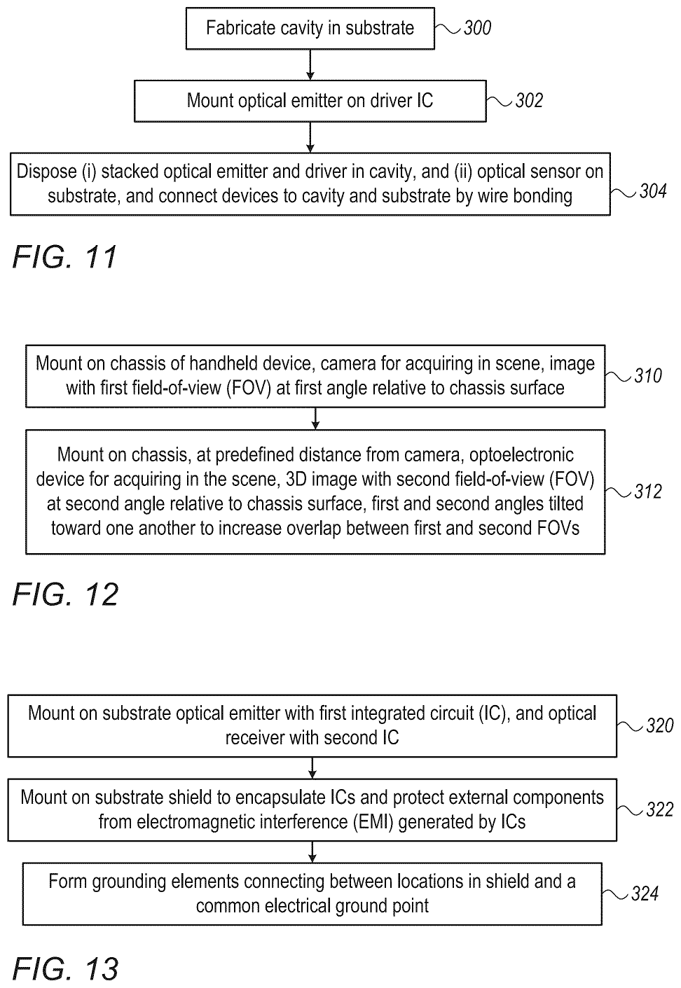

FIG. 11 is a flow chart that schematically illustrates a method for producing module 20, in accordance with an embodiment of the invention.

The method begins at a cavity formation step 300 with forming cavity 15 in substrate 26, as described in detail in FIG. 2 above. At a mounting step 302, which is typically carried out in parallel with step 300, the optical emitter 22 is mounted on driver 33 in accordance with the VCSEL over Silicon (VoS) configuration shown in inset 86 of FIG. 4 above. It is noted that the VoS configuration comprises optical emitter 22 being connected to driver 33 via bumps 69, as described in detail in FIG. 4 above.

At an optoelectronic device mounting step 304 that concludes the method, the stack of driver 33 and optical emitter 22 is (i) disposed within cavity 15, as described in detail in FIG. 2 above, or (ii) attached to the SMT, which is disposed in cavity 15. Moreover, optical sensor 24 is disposed on substrate 26 (or attached to the SMT, which is mounted on substrate 26). In some embodiments, optical emitter 22 and optical sensor 24 are electrically connected to CB 35 (directly or via electrical connections) using wire bonding 64, as described in detail, for example, in FIG. 4 above.

In some embodiments, lenses 32 and 43 are assembled in case 38 (shown in FIGS. 2, 3A and 3B above) to form optical transmitter 21 and optical receiver 23, respectively.

FIG. 12 is a flow chart that schematically illustrates a method for producing handheld device 170, in accordance with an embodiment of the invention.

The method begins at a camera mounting step 310 with mounting on surface 179 of chassis 180, camera 172 for acquiring 2D image. As described in FIG. 10 above, the 2D image has FOV 176, which is orthogonal to axis 171 directed at right angle 173 relative to outer surface 179 of device 170.

At an optoelectronic device mounting step 312 that concludes the method, slanted base plate 188 is placed over chassis 180 (or alternatively, base plate 188 and chassis 180 are provided together as a single continuous piece, as described in FIG. 10 above, and are placed) at a predefined distance from camera 172, and module 20 is placed over base plate 188 for acquiring 3D image having FOV 186. As described in detail in FIG. 10 above, FOV 186 is orthogonal to axis 181 directed at acute angle 183 relative to outer surface 179 of device 170.

In some embodiments, angles 173 and 183 are tilted toward one another, so as to increase the size 194 of overlap 195 between FOVs 176 and 186, as described in detail in FIG. 10 above.

In other embodiments, instead of tilting the entire structure of module 20, tilting beams 71 at angle 184 may be carried out using other techniques. For example, housing 190 may be disposed directly on surface 179, so that surface 192 of housing 190 may be parallel to the plain of chassis 180. In such embodiments, housing 190 is configured to contain (i) optical transmitter 21 having transmit axis 31, and optical receiver 23 having a receive axis 45, and at least one of transmit axis 31 and receive axis 45 is parallel with axis 181. In this configuration, axes 171 and 181 are still tilted toward one another, so as to increase the size 194 of overlap 195 between FOVs 176 and 186.

Additionally, or alternatively, the increased size 194 of overlap 195 may be obtained without tilting beams 71, in other words, directing beams 71 orthogonal to outer surface 179, and/or having module 20 and surface 192 parallel with outer surface 179. This configuration enables an increase in the width of one or both (i) lenses 32 (of lens assembly 30) of optical transmitter 21, and (ii) lenses 43 of optical receiver 23, resulting in increasing the size of FOV 176, and thereby, increases the size 194 of overlap 195 between FOVs 176 and 186.

FIG. 13 is a flow chart that schematically illustrates a method for producing module 20 and shielding components in proximity with module 20, in accordance with an embodiment of the invention.

The method begins at a first IC mounting step 320 with (i) mounting driver 33 and optical emitter 22 in cavity 15 of substrate 26, and (ii) mounting optical sensor 24 over substrate 26, as described in detail in FIGS. 1 and 2 above.

At a shield mounting step 322, case 38 is mounted on substrate 26. In the present example, case 38 functions as a shield to protect devices from electromagnetic interference (EMI) generated during the operation of module 20 and the electronic device comprising module 20. As described in FIG. 2 above, the EMI may comprise: (i) the first EMI generated by one or more of the aforementioned ICs of module 20 (e.g., mainly by driver 33, but also by optical emitter 22, and optical sensor 24), and (ii) the second EMI generated by EMI sources external to module 20, such as the aforementioned antennas of wireless communications. As such, case 38 protects: (i) devices external to module 20 from the first EMI, and (ii) the components of module 20 from the second EMI.

At a grounding step 324 that concludes the method, grounding elements 62 are formed for connecting between (i) multiple dedicated locations of case 38, and (ii) a common electrical ground point (e.g., CB 35). As shown in FIG. 3B above, case 38 has multiple dedicated locations for disposing multiple electrically conductive grounding elements 62. For example, case 38 has four dedicated locations 60a, 60b, 60c and 60d at the four apexes or corners of case 38, for disposing four grounding elements, respectively. As shown and described in FIG. 3B above, grounding element 62 is soldered to substrate 26, to electrically connect between case 38 and substrate 26 for grounding purposes. As such, grounding elements 62 are configured to reduce impendence in module 20 and serve as an escape route for grounding any undesired charge build up on case 38.

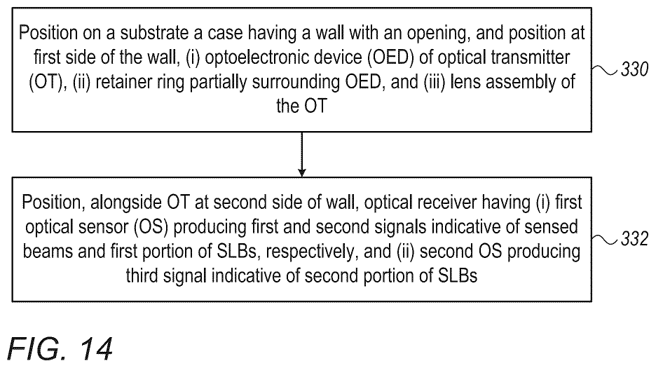

FIG. 14 is a flow chart that schematically illustrates a method for producing a portion of module 20, in accordance with another embodiment of the invention.

In some embodiments, (i) optical emitter 22 stacked over driver 33 (VoS), and (ii) optical sensor 24 are positioned on substrate as 26, described above. Subsequently, the method begins at an optical transmitter and retainer ring positioning step 330 with positioning case 38 on substrate 26. Case 38 has wall 66 formed between openings 58 and 59, which are configured to contain and position lens assemblies 30 and 42, respectively, as shown in FIGS. 2, and 3A above, and described in detail in FIG. 3B above. As described above, the devices of optical transmitter 21 (e.g., the stack of emitter 22 over driver 33) are positioned on substrate 26, typically before placing case 38, at the first side of wall 66 that has opening 77. In the present example, retainer ring 55 is disposed on the bottom of the lenses 32 for partially surrounding optical emitter 22. Retainer ring 55 has opening 57, which is configured to direct beams 74 through opening 77, as described in detail in FIGS. 3A and 3B above. Moreover, optical transmitter 21 comprises lens assembly 30, which is assembled in opening 58 of case 38 (after case 38 is disposed on substrate 26), as described above.

At an optical receiver positioning step 332 that concludes the method, optical receiver 23 is placed alongside optical transmitter 21, but at the second side of wall 66. In the present example, optical sensors 24 and 25 are placed at two separate positions on substrate 26 before disposing case 38 on substrate 26, but the intended positions of optical sensors 24 and 25 are at the second side of wall 66. Moreover, after disposing case 38 on substrate 26, lens assembly 42 is assembled in opening 59 of case 38, as described above. Based on the geometry and reflecting surfaces of retainer ring 55, (i) beam 75, which is the first portion of beam 74, passes through opening 77 and impinges on the surface of optical sensor 25, and (ii) beam 76, which is the second portion of beam 74, and is typically substantially smaller than the first portion of beams 74 (e.g., beams 75), is deflected in wall 66 and passes through opening 77, and subsequently, impinges on the surface of optical sensor 24.

In some embodiments, CB 35 is connected to the terminals of module 20, so that optical sensors 24 and 25 are electrically connected to the processor described in FIGS. 1 and 2 above. It is noted that the processor is typically but not necessarily mounted on CB 35 but could alternatively be integrated within module 20. It is noted that in response to the beams 72 reflected from scene 93, and the SLBs, such as beams 75 and 76 described above, the processor receives from optical sensors 24 and 25 at least three signals indicative of the respective intensities of at least beams 72, 75 and 76, so as to produce the 3D image described above.

It will thus be appreciated that the embodiments described above are cited by way of example, and that the present invention is not limited to what has been particularly shown and described hereinabove. Rather, the scope of the present invention includes both combinations and sub-combinations of the various features described hereinabove, as well as variations and modifications thereof which would occur to persons skilled in the art upon reading the foregoing description and which are not disclosed in the prior art.

1. An optoelectronic assembly, comprising:
a substrate having a cavity;
an optoelectronic device, which is disposed over the cavity and comprises an array of multiple emitters configured to emit a predefined number of light beams in response to receiving one or more electrical signals; and
an integrated circuit (IC), which is mounted within the cavity, between the substrate and the optoelectronic device, and is configured to drive the one or more electrical signals to the optoelectronic device.

2. The optoelectronic assembly according to claim 1, and comprising electrically conductive bumps, which are disposed between the IC and the optoelectronic device, and are configured to conduct the one or more electrical signals.

3. The optoelectronic assembly according to claim 1, and comprising a lens assembly mounted over the optoelectronic device and configured to direct a given number of light beams to a scene opposite the lens assembly, wherein the given number equals the predefined number of the light beams emitted from the optoelectronic device.

4. The optoelectronic assembly according to claim 3, and comprising a housing, which is mounted over the substrate and is configured to shield at least the optoelectronic device and the IC from electromagnetic interference (EMI), wherein at least a portion of the lens assembly extends out of the housing.

5. The optoelectronic assembly according to claim 3, wherein the optoelectronic assembly is mounted on a handheld device and configured to direct the given number of light beams to the scene for producing a three-dimensional (3D) image of the scene, wherein the 3D image has a field-of-view (FOV) orthogonal to an axis, which is directed at an acute angle relative to a plain of a chassis of the handheld device.

6. The optoelectronic assembly according to claim 1, and comprising a filler, which is disposed between an edge of the IC and the cavity, and surrounds the edge of the IC, the filler is configured to protect the IC from light radiation impinging on at least the edge of the IC.

7. The optoelectronic assembly according to claim 6, wherein the light radiation comprises a portion of the light beams reflected from one or both of the lens assembly and the housing, and wherein the filler comprises resin configured to attenuate at least a predefined wavelength of the reflected light beams.

8. A handheld device, comprising:
a camera, which is configured to acquire at least an image of a scene, wherein the image of the camera has a first field-of-view (FOV) orthogonal to a first axis directed at a first angle relative to a plain of a chassis of the handheld device; and
an optoelectronic device, disposed at a predefined distance from the camera, the optoelectronic device comprising: (i) an optical transmitter configured to direct multiple light beams toward the scene, and (ii) an optical receiver positioned alongside the optical transmitter, the optical receiver comprising a time-of-flight (TOF) imaging sensor, which configured to generate, based on a reflection of the multiple light beams directed toward the scene, a signal indicative of a three-dimensional (3D) image of the scene, wherein the 3D image has a second FOV orthogonal to a second axis directed at a second angle relative to the plain of the chassis, wherein the second angle is different from the first angle, and wherein the first and second angles are tilted toward one another to increase an overlap between the first and second FOVs.

9. The handheld device according to claim 8, and comprising a base plate, which is slanted relative to the plain of the chassis, and wherein the camera or the optoelectronic device is mounted on the base plate.

10. The handheld device according to claim 9, wherein the base plate has a third axis, which is slanted at a third angle relative to the plain of the chassis, wherein a sum of the second angle and the third angle equals a right angle, and wherein the optoelectronic device is mounted on the base plate.

11. The handheld device according to claim 10, wherein the optoelectronic device comprises a substrate, which is (i) disposed on the base plate, and (ii) slanted relative to the plain of the chassis, and wherein the optical transmitter and the optical receiver are mounted on the substrate.

12. The handheld device according to claim 11, and comprising a first housing disposed on the substrate, the first housing is configured to contain the optical transmitter and the optical receiver, wherein the optical transmitter has a transmit axis, and the optical receiver has a receive axis, and wherein at least one of the transmit axis and the receive axis is parallel to the second axis.

13. The handheld device according to claim 12, wherein the first housing is slanted, and comprising a second housing of the electronic device, the second housing is disposed on the first housing and has an asymmetric shape.

14. The handheld device according to claim 13, wherein the second housing has (i) a first section disposed on a first side of the first housing at a first distance from the plain of the chassis, and (ii) a second section disposed on a second side of the first housing at a second distance from the plain of the chassis, different from the first distance.

15. The handheld device according to claim 13, wherein the second housing is configured to hold a plate configured to seal at least one of the optical transmitter and the optical receiver of the optoelectronic device.

16. The handheld device according to claim 15, wherein the plate has an inner surface facing the optoelectronic device and an outer surface opposite the inner surface, and wherein at least one of the inner surface and the outer surface is parallel with the plain of the chassis.

17. An optoelectronic device, comprising:
a substrate;
an optical transmitter having a first integrated circuit (IC), and an optical receiver having a second IC, wherein the optical transmitter and the optical receiver are mounted on the substrate, and wherein the first and second ICs generate electromagnetic interference (EMI) while being operated;
a shield assembly, which is mounted over the substrate and is configured to encapsulate at least the first and second ICs, and to protect components positioned externally to the optoelectronic device from the EMI generated by the first and second ICs; and
two or more grounding elements connecting between respective two or more dedicated locations of the shield and a common electrical ground point.

18. The optoelectronic device according to claim 17, wherein the shield assembly has a polygonal shape, and wherein the two or more dedicated locations comprise two or more apexes of the polygonal shape, respectively.

19. The optoelectronic device according to claim 17, wherein the shield assembly is configured to protect at least one of the first and second ICs from an external EMI generated by an electromagnetic source positioned externally to the optoelectronic device.

20. An optoelectronic assembly, comprising:
an optical transmitter positioned at a first side of a wall, the optical transmitter comprising:
an optoelectronic device configured to emit multiple light beams, wherein a first portion of the light beams is directed toward a scene, and a second portion of the light beams comprise internal stray light beams (SLBs) that are not directed toward the scene; and
a retainer ring, which is at least partially surrounding the optoelectronic device, and is configured to direct the internal SLBs through an opening in the wall; and
an optical receiver positioned alongside the optical transmitter at a second side of the wall, the optical receiver comprising:
a first array of imaging pixels, which is configured to generate a first signal based on the emitted light beams reflected from the scene, and a second signal responsively to receiving first internal SLBs among the SLBs that pass through the opening; and
a second array of imaging pixels, which is separated from the first array, and is configured to generate a third signal responsively to receiving second internal SLBs among the SLBs that pass through the opening.

21. The optoelectronic assembly according to claim 20, wherein the first array of imaging pixels comprises a time-of-flight (TOF) imaging sensor, and further comprising a processor, which is configured to produce a three-dimensional (3D) image of the scene based on the first signal and at least one of the second and third signals, wherein the second and third signals serve as TOF reference for producing the 3D image.

22. The optoelectronic assembly according to claim 20, and comprising: (i) a lens assembly mounted over the optoelectronic device, the lens assembly comprising at least first and second lens, and is configured to direct at least a portion of the light beams toward the scene, and (ii) a lens aperture, mounted between the first lens and the second lens, and configured to block at least a portion of external SLBs being reflected from a glass covering the optoelectronic assembly into the lens assembly.

23. The optoelectronic assembly according to claim 22, wherein the lens aperture has a horus shape having an outer diameter and an inner diameter, and wherein the size of at least one of the outer and inner diameters determines the portion of the external SLBs blocked by the lens aperture.

24. The optoelectronic assembly according to claim 22, and comprising a stack of multiple layers, which are formed on an outer surface of at least one of the first lens and the second lens, the stack of multiple layers is configured to selectively reflect at least a portion of the internal SLBs at predefined angles through the opening in the wall toward at least one of the first and second arrays of imaging pixels.

25. The optoelectronic assembly according to claim 24, wherein the stack of multiple layers comprises alternating layers of (i) titanium oxide and (ii) silicon oxide which are configured to control an intensity of at least one of the first and second internal SLBs impinging on a surface of at least one of the first and second arrays of imaging pixels, respectively.
